(19) United States
(12) Patent Application Publication
(10) Pub. No.: US 2025/0389877 A1
(43) Pub. Date: Dec. 25, 2025

(54) EXPOSURE DEVICE, METHOD OF MANUFACTURING DIFFRACTIVE OPTICAL ELEMENT, OPTICAL SHEET, AND ALIGNMENT FILM

(71) Applicant: FUJIFILM Corporation, Tokyo (JP)

(72) Inventors: Yohei HAMACHI, Minamiashigara-shi (JP); Makoto KAMO, Minamiashigara-shi (JP)

(73) Assignee: FUJIFILM Corporation, Tokyo (JP)

(21) Appl. No.: 19/317,229

(22) Filed: Sep. 3, 2025

Related U.S. Application Data
(63) Continuation of application No. PCT/JP2024/012371, filed on Mar. 27, 2024.

(30) Foreign Application Priority Data
Mar. 31, 2023 (JP) 2023-057170

(51) Int. Cl. G02B 5/18; G03F 7/00; G03F 7/38; G03F 9/00

(52) U.S. Cl. CPC G02B 5/1857; G02B 5/1828; G03F 7/0005; G03F 7/38; G03F 7/70325; G03F 7/70358; G03F 9/7065; G03F 9/7076

(57) ABSTRACT

An exposure device for interference exposure that combines polarized light beams orthogonal to each other while suppressing non-interference exposure regions where only one polarized light is emitted. The exposure device includes a light source, a beam splitter, a beam combiner, and a focusing element disposed on one optical path of light split by the beam splitter. An optical element converts the split light into linearly polarized light beams orthogonal to each other. A polarizer is positioned between the beam combiner and a polarization conversion element to shield part of the linearly polarized light focused by the focusing element. A light-shielding member is also provided on the optical path of the combined light to block part of the linearly polarized light not focused by the focusing element. A method of manufacturing a diffractive optical element, an optical sheet, and an alignment film using the exposure device are also provided.

### CROSS-REFERENCE TO RELATED APPLICATIONS

This application is a Continuation of PCT International Application No. PCT/JP2024/012371 filed on Mar. 27, 2024, which claims priority under 35 U.S.C. § 119 (a) to Japanese Patent Application No. 2023-057170 filed on Mar. 31, 2023. The above applications are hereby expressly incorporated by reference, in their entirety, into the present application.

### BACKGROUND OF THE INVENTION

### 1. Field of the Invention

The present invention relates to an exposure device that performs interference exposure, a method of manufacturing a diffractive optical element using the exposure device, and an optical sheet and an alignment film.

### 2. Description of the Related Art

An exposure device that causes two beams of light to interfere with each other to form an interference pattern is used for manufacturing various optical elements such as a liquid crystal diffraction element.

As such an exposure device, for example, an exposure device shown in FIG. 18 is described in “Fabrication of ideal geometric-phase holograms with arbitrary wavefronts”, Optica Vol. 2, No. 11, November 2015, pp. 958-964.

An exposure device 100 includes a light source 102 that emits light M having coherence, a polarization beam splitter 104 that splits the light M emitted from the light source 102 into linearly polarized lights orthogonal to each other, a mirror 106a disposed on one optical path and a mirror 106b disposed on the other optical path of the light split by the polarization beam splitter 104, a focusing element 108, a beam combiner element 110, and a λ/4 plate 112.

In the exposure device 100, the light M having coherence emitted from the light source 102 is split into, for example, P-polarized light MP and S-polarized light MS by the polarization beam splitter 104.

The S-polarized light MS split by the polarization beam splitter 104 is reflected from the mirror 106a, transmits through the focusing element 108, and is incident into the beam combiner element 110. On the other hand, the P-polarized light MP split by the polarization beam splitter 104 is reflected from the mirror 106b and is incident into the beam combiner element 110.

The P-polarized light MP is reflected from the beam combiner element 110. On the other hand, the S-polarized light MS transmitted through the focusing element 108 is transmitted through the beam combiner element 110. As a result, the P-polarized light MP and the S-polarized light MS are combined with each other by the beam combiner element 110 to interfere with each other.

The P-polarized light MP and the S-polarized light MS are right circularly polarized light and left circularly polarized light by the λ/4 plate 112 depending on polarization directions, and are incident into, for example, a photosensitive material Z to form an interference pattern. For example, in a case where the photosensitive material Z includes a coating film that includes a compound having a photo-aligned group, an alignment film having an alignment pattern corresponding to the interference pattern is obtained.

In the exposure device 100, an interference pattern having a pattern in which a straight line changes while continuously rotating in one direction in a radial shape from an inner side toward an outer side as conceptually shown in FIG. 2 described below is formed.

### SUMMARY OF THE INVENTION

As described above, in the exposure device 100 described in “Fabrication of ideal geometric-phase holograms with arbitrary wavefronts”, Optica Vol. 2, No. 11, November 2015, pp. 958-964, the photosensitive material Z is exposed to the interference light by combining the light focused by the focusing element 108 and the light that does not transmit through the focusing element 108. In the example shown in the drawing, the light focused by the focusing element 108 is the S-polarized light MS, and the light that does not transmit through the focusing element 108 is the P-polarized light MP.

That is, the exposure device 100 performs the interference exposure by combining a plane wave (parallel light) having no spread and a spherical wave having a spread.

Therefore, in the exposure device 100, as shown in an enlarged view of a circle C in FIG. 18, in the photosensitive material Z, an effective region exposed to an interference light of the plane wave (P-polarized light MP) and the spherical wave (S-polarized light MS) and a non-interference exposure region L exposed only to a spherical wave having a spread are generated.

This non-interference exposure region is a wasted region that cannot be used as the optical element.

For example, in the manufacturing of the optical element, a large number of optical elements are manufactured on one photosensitive material Z by repeatedly performing exposure by the exposure device 100 and relative movement between the exposure device 100 and the photosensitive material Z using the photosensitive material Z capable of forming a large number of optical elements.

In this case, the exposure and the relative movement between the exposure device 100 and the photosensitive material Z are repeated such that the exposure regions of the exposure device 100 do not overlap each other. On the other hand, in consideration of the yield, it is preferable to form as many optical elements as possible on one photosensitive material Z. For this purpose, it is preferable that the exposure regions are as close to each other as possible.

However, in a case where there is the non-interference exposure region L as shown in FIG. 18, it is necessary to perform the exposure such that the non-interference exposure regions L do not overlap each other. That is, in a case where the non-interference exposure region L is present, the exposure region is larger than the actual optical element. Therefore, in a case where the non-interference exposure region L is present, the number of optical elements that can be formed on one photosensitive material Z is reduced, and the yield is lowered.

An object of the present invention is to solve the above-described problem of the related art, and to provide an exposure device that can suppress a non-interference exposure region where only one polarized light is emitted in an exposure device that performs interference exposure by combining polarized lights orthogonal to each other, a method of manufacturing a diffractive optical element using the exposure device, and an optical sheet and an alignment film.

In order to solve the problems, the present invention has the following configuration.
[1] An exposure device comprising:
a light source;
a beam splitter element that splits light emitted from the light source;
a beam combiner element that has a first surface on which the light split by the beam splitter element is incident and through which at least a part of incidence light is transmitted and a second surface on which the other light split by the beam splitter element is incident and on which at least a part of incidence light is reflected, and emits light obtained by combining the light transmitted through the first surface and the light reflected from the second surface;
a focusing element that is provided on an optical path of first light incident on the first surface of the beam combiner element or on an optical path of second light incident on the second surface of the beam combiner element, and focuses the light;
an optical element that is provided between the light source and the beam combiner element, and converts the first light and the second light into linearly polarized lights orthogonal to each other;
a polarization conversion element that is disposed on an optical path of the light combined by the beam combiner element;
a light shielding member that is disposed on the optical path of the light combined by the beam combiner element, and shields a part of the linearly polarized light that is not focused by the focusing element; and
a polarizer that is disposed between the beam combiner element and the polarization conversion element, and shields a part of the linearly polarized light that is focused by the focusing element.
[2] The exposure device according to [1],
in which a transmissive region of the linearly polarized light in the polarizer is narrower than a transmissive region of the light in the light shielding member.
[3] The exposure device according to [1] or [2],
in which the polarizer and the light shielding member are provided at the same position in a traveling direction of the light combined by the beam combiner element, and
the light shielding member has an opening and the polarizer is provided at the opening of the light shielding member.
[4] The exposure device according to any one of [1] to [3],
in which the polarizer and the light shielding member are provided at different positions in a traveling direction of the light combined by the beam combiner element.
[5] The exposure device according to any one of [1] to [4], further comprising:
a support member that supports an exposure target; and
a moving unit that relatively moves the exposure device and the support member.
[6] A method of manufacturing a diffractive optical element, comprising:
an exposure step of exposing an alignment film including a compound having a photo-aligned group using the exposure device according to any one of [1] to [5]; and
a film forming step of applying a composition including a liquid crystal compound to the exposed alignment film and drying the composition.
[7] The method of manufacturing a diffractive optical element according to [6],
in which in the exposure step, after the alignment film is exposed, the exposure of the alignment film is repeatedly performed again a plurality of times by relatively moving the alignment film and the exposure device in a plane direction of the alignment film.
[8] An optical sheet, comprising:
a plurality of diffractive optical elements each having a concentric circular shape of a liquid crystal alignment pattern in which an orientation of an optical axis derived from a liquid crystal compound changes while continuously rotating in at least one in-plane direction,
in which a total area of non-diffractive optical element regions present between the diffractive optical elements is 15% or less of an area of the diffractive optical elements.
[9] An alignment film, comprising:
a plurality of concentric circular alignment patterns each having a pattern in which an orientation of a line segment changes while continuously rotating in at least one direction,
in which a total area of non-alignment pattern regions present between the alignment patterns is 15% or less of an area of the alignment patterns.

According to the present invention, in the exposure device that performs interference exposure by combining polarized lights orthogonal to each other, it is possible to suppress a non-interference exposure region where only one polarized light is emitted.

### BRIEF DESCRIPTION OF THE DRAWINGS

FIG. 1 is a diagram conceptually showing an example of an exposure device according to the present invention.

FIG. 2 is a diagram conceptually showing an example of an interference pattern formed by the exposure device according to the present invention.

FIG. 3 is a conceptual diagram for describing an action of the exposure device in FIG. 1.

FIG. 4 is a conceptual diagram for describing an action of another example of the exposure device according to the present invention.

FIG. 5 is a conceptual diagram for describing an action of another example of the exposure device according to the present invention.

FIG. 6 is a conceptual diagram for describing an action of another example of the exposure device according to the present invention.

FIG. 7 is a conceptual diagram for describing an action of another example of the exposure device according to the present invention.

FIG. 8 is a schematic plan view of an example of a diffractive optical element manufactured using a manufacturing method according to the present invention.

FIG. 9 is a schematic cross-sectional view of the example of the diffractive optical element manufactured using the manufacturing method according to the present invention.

FIG. 10 is a conceptual diagram for describing the diffractive optical element shown in FIG. 9.

FIG. 11 is a conceptual diagram for describing an action of the diffractive optical element manufactured using the manufacturing method according to the present invention.

FIG. 12 is a conceptual diagram for describing the action of the diffractive optical element manufactured using the manufacturing method according to the present invention.

FIG. 13 is a schematic cross-sectional view of another example of the diffractive optical element manufactured using the manufacturing method according to the present invention.

FIG. 14 is a conceptual diagram for describing an action of the diffractive optical element shown in FIG. 13.

FIG. 15 is a conceptual diagram for describing the diffractive optical element shown in FIG. 13.

FIG. 16 is a conceptual diagram for describing the action of the diffractive optical element shown in FIG. 13.

FIG. 17 is a conceptual diagram for describing an optical sheet and an alignment film according to the present invention.

FIG. 18 is a diagram conceptually showing an example of an exposure device in the related art.

### DESCRIPTION OF THE PREFERRED EMBODIMENTS

Hereinafter, an exposure device, a method of manufacturing a diffractive optical element, an optical sheet, and an alignment film according to the embodiment of the present invention will be described in detail based on preferred examples shown in the accompanying drawings.

The following description regarding configuration requirements has been made based on a representative embodiment of the present invention. However, the present invention is not limited to the embodiment.

Further, all the drawings described below are conceptual views for describing the present invention. A size, a thickness, a positional relationship, and the like of each of members, portions, and the like do not necessarily match the actual ones.

In the present specification, a numerical range represented by “to” means a range including numerical values before and after “to” as lower limit values and upper limit values.

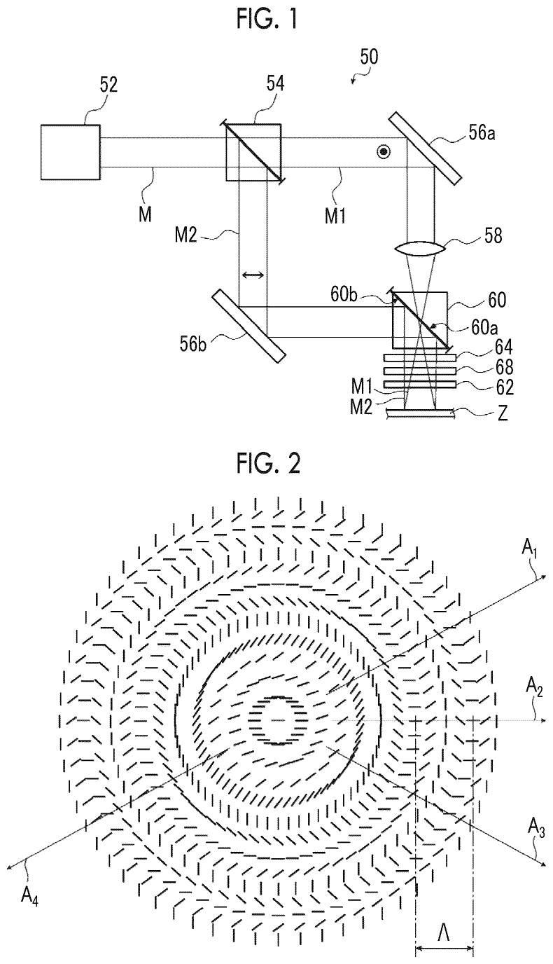

FIG. 1 conceptually shows an example of the exposure device according to the embodiment of the present invention.

An exposure device 50 shown in FIG. 1 includes a light source 52, a polarization beam splitter 54, mirrors 56a and 56b, a focusing element 58, a beam combiner element 60, and a polarization conversion element 62.

Further, the exposure device 50 in the example shown in the drawing includes a light shielding member 64 and a polarizer 68 between the beam combiner element 60 and the polarization conversion element 62.

In the exposure device 50, the light M having coherence emitted from the light source 52 is split into linearly polarized lights orthogonal to each other by the polarization beam splitter 54, one of the linearly polarized lights is focused by the focusing element 58, the two linearly polarized lights are combined by the beam combiner element 60, and the combined light is converted into circularly polarized light by the polarization conversion element 62.

The exposure device 50 generates an interference fringe by causing two circularly polarized lights having opposite turning directions to interfere with each other and to be incident into a photosensitive material Z, and exposes the photosensitive material Z to form an interference pattern (alignment pattern) on the photosensitive material Z.

In such an exposure device 50, the polarizer 68 shields a part of the linearly polarized light focused by the focusing element 58. On the other hand, the light shielding member 64 shields a part of the linearly polarized light that is not focused by the focusing element 58.

The exposure device 50 according to the embodiment of the present invention includes the light shielding member 64 and the polarizer 68. Therefore, in the photosensitive material Z, the formation of the non-interference exposure region exposed to only the light focused by the focusing element 58 is suppressed.

The above-described point will be described in detail below.

In the exposure device 50, a well-known light source can be used as the light source 52 as long as the emitted light has coherence. In particular, as the light source having excellent coherence, various laser light sources are suitably used.

The light M having coherence emitted from the light source 52 is incident into the polarization beam splitter 54.

The polarization beam splitter 54 splits the light M having coherence emitted from the light source 52 into first light M1 and second light M2 that are linearly polarized lights orthogonal to each other. The polarization beam splitter 54 in the example shown in the drawing splits, for example, the light M having coherence into the first light M1 of S-polarized light and the second light M2 of P-polarized light. The first light M1 is the first light in the present invention, and the second light M2 is the second light in the present invention.

That is, the polarization beam splitter 54 is a beam splitter element according to the embodiment of the present invention and also serves as an optical element that converts the first light and the second light into linearly polarized lights orthogonal to each other.

The S-polarized light is linearly polarized light in a direction orthogonal to the reflecting surface. On the other hand, the P-polarized light is linearly polarized light in a direction parallel to the reflecting surface.

In addition, in the present invention, the polarized lights orthogonal to each other refers to polarized light having opposite characteristics, that is, polarized light positioned on opposite sides of a Poincare sphere. Specifically, the polarized lights orthogonal to each other are linearly polarized lights orthogonal to each other in terms of linearly polarized light and are right circularly polarized light and left circularly polarized light in terms of circularly polarized light.

As the polarization beam splitter 54, various well-known polarization beam splitters such as a cube type or a plate type can be used as long as they can split the light M having coherence into linearly polarized lights orthogonal to each other.

In the exposure device according to the embodiment of the present invention, the first light and the second light incident into the beam combiner element 60 are not limited to being converted into linearly polarized lights orthogonal to each other using the polarization beam splitter.

In the exposure device according to the embodiment of the present invention, for example, a non-polarization beam splitter such as a half mirror and a linear polarizer may be used to convert the first light and the second light incident into the beam combiner element 60 into linearly polarized lights orthogonal to each other. In this case, first, the light M having coherence emitted from the light source 52 is split using the non-polarization beam splitter. In addition, the linear polarizer may be disposed on the optical path of each light between the non-polarization beam splitter and the beam combiner element 60 to convert the light incident into the beam combiner element 60 into linearly polarized lights orthogonal to each other.

In the present invention, the polarizer (linear polarizer) is not limited, and may be a reflective-type polarizer or an absorptive-type polarizer, including the polarizer 68 described below.

Therefore, as the polarizer, various well-known linear polarizers (linearly polarizing plates) such as an iodine-based polarizer, a dye-based polarizer using a dichroic dye, a polyene-based polarizer, a wire grid-type polarizer, and a film obtained by stretching a dielectric multi-layer film described in JP2011-053705A can be used.

The first light M1 (S-polarized light) is reflected from the mirror 56a, is focused by the focusing element 58, and is incident into the beam combiner element 60. In the example shown in the drawing, the focusing element 58 is, for example, a convex lens. Accordingly, the light transmitted through the focusing element 58 is focused at the focal point and has a spread after the focal point.

On the other hand, the second light M2 (P-polarized light) is reflected from the mirror 56b and is incident into the beam combiner element 60.

The beam combiner element 60 includes a beam combiner element that includes a first surface 60a through which at least a part of incidence light transmits, and a second surface 60b from which at least a part of the incidence light is reflected. The light incident on and transmitted through the first surface 60a of the beam combiner element 60 and the light incident on and reflected from the second surface 60b of the beam combiner element 60 are combined and emitted from the beam combiner element 60.

In the following description, in order to simplify the sentences, “at least a part” in the description “at least a part of incidence light transmits”, “at least a part of the incidence light is reflected”, and the like are omitted.

In the exposure device 50 in the example shown in the drawing, the first light M1 that has been transmitted through and focused by the focusing element 58 is incident on and transmitted through the first surface 60a of the beam combiner element 60, and the second light M2 is incident on and reflected from the second surface 60b.

The first light M1 incident on and transmitted through the first surface 60a and the second light M2 incident on and reflected from the second surface 60b are combined as shown in FIG. 1. As described above, the first light M1 and the second light M2 are originally split from the same light M having coherence. Accordingly, the first light M1 and the second light M2 that are combined interfere with each other.

The beam combiner element 60 is not limited, and any well-known elements can be used as long as they include the first surface 60a through which incidence light transmits and the second surface 60b from which the incidence light is reflected and can combine the light incident on and transmitted through the first surface 60a and the light reflected from the second surface 60b.

That is, as the beam combiner element 60, for example, a well-known beam splitter such as a half mirror, a cube type, and a plate type, and various well-known beam combiner elements such as a beam combiner element can be used.

A part of the first light M1 and the second light M2 that are combined by the beam combiner element 60 is shielded by the light shielding member 64 and the polarizer 68, and are then converted into circularly polarized light by the polarization conversion element 62. The light shielding member 64 and the polarizer 68 will be described in detail below.

As described above, the first light M1 and the second light M2 are linearly polarized lights orthogonal to each other, and are, for example, the S-polarized light and the P-polarized light. Accordingly, by the polarization conversion element 62, the first light M1 is converted into right circularly polarized light, and the second light M2 is converted into left circularly polarized light. Alternatively, by the polarization conversion element 62, the first light M1 is converted into left circularly polarized light, and the second light M2 is converted into right circularly polarized light.

Preferable examples of the polarization conversion element 62 include a so-called ¼ wave plate (¼ retardation plate, 24 plate) that has an in-plane retardation (retardation Re) of about ¼ wavelength at the wavelength of the incidence light, that is, the first light M1 and the second light M2.

As the ¼ wave plate, various well-known ¼ wave plates can be used. Examples thereof include a stretched polycarbonate film, a stretched norbornene-based polymer film, a transparent film in which inorganic particles having birefringence such as strontium carbonate are included and aligned, a thin film in which oblique deposition of an inorganic dielectric is performed on a support, a film in which the polymerizable liquid crystal compound is uniaxially aligned and the alignment is immobilized, and a film in which the liquid crystal compound is uniaxially aligned and the alignment is immobilized.

In addition, the polarization conversion element 62 may be used in combination with a plurality of optical elements. In this case, in the form where the plurality of optical elements are combined, the retardation measured using a method described below may be about the ¼ wavelength.

As described above, the exposure device 50 generates interference fringes by causing two circularly polarized lights having opposite turning directions to interfere with each other and to be incident into the photosensitive material Z, and exposes the photosensitive material Z to form an interference pattern on the photosensitive material Z.

Specifically, as conceptually shown in FIG. 2, the interference pattern formed in the photosensitive material Z by the exposure device 50 is a concentric circular interference pattern (alignment pattern) in which a pattern in which a short straight line changes while continuously rotating in one direction is provided in a concentric circular shape from the inner side toward the outer side. In other words, the interference pattern formed in the photosensitive material Z by the exposure device 50 is an interference pattern having a pattern in which a short straight line changes while continuously rotating in one direction in a radial shape as shown in FIG. 2.

In the exposure device 50, due to the interference between right circularly polarized light and left circularly polarized light, the polarization state of light to be emitted on the photosensitive material Z periodically changes according to the interference fringe.

Here, as shown in FIG. 1, the first light M1 is focused by the focusing element 58 (convex lens) and has a spread after the focal point. In other words, the first light M1 diffuses after the focal point of the focusing element 58. That is, in the first light M1 and the second light M2 to be interfered with, the intersecting angle between the left circularly polarized light and the right circularly polarized light changes from the inner side toward the outer side of the concentric circle.

As a result, in the photosensitive material Z, a concentric circular interference pattern in which the interference pattern periodically changes and the period of the change decreases from the inner side toward the outer side is obtained.

Specifically, in the interference pattern, a short straight line changes while continuously rotating in a plurality of directions from the center toward the outer side, for example, a direction indicated by an arrow A₁, a direction indicated by an arrow A₂, a direction indicated by an arrow A₃, a direction indicated by an arrow A₄, or . . . . In the following description, the short straight line of which the orientation changes while continuously rotating will be referred to as “short line” for convenience of description.

The rotation direction of the short line is the same direction in all of the directions (one direction). In the example shown in the drawing, in all the directions including the direction indicated by the arrow A₁, the direction indicated by the arrow A₂, the direction indicated by the arrow A₃, and the direction indicated by the arrow A₄, the rotation direction of the short line is counterclockwise.

That is, in a case where the arrow A₁ and the arrow A₄ are assumed as one straight line, the rotation direction of the short line is reversed at the center on the straight line. For example, the straight line formed by the arrow A₁ and the arrow A₄ is directed in the right direction (arrow A₁ direction) in the drawing. In this case, the short line initially rotates clockwise from the outer side toward the center, the rotation direction is reversed at the center, and then the short line rotates counterclockwise from the center toward the outer side.

The rotation direction of the short line is not limited to the direction shown in FIG. 2 and may be opposite to the rotation direction shown in FIG. 2.

In addition, in the interference pattern, in a case where a length over which the orientation of the short line rotates by 180° in the one direction in which the direction of the short line changes while continuously rotating is set as a single period A, the length of the single period A gradually decreases from the inner side toward the outer side. The single period A will be described in detail below.

In the exposure device according to the embodiment of the present invention, the focusing element 58 is not limited to the convex lens, and various well-known focusing elements such as a Fresnel lens and an aspherical lens can be used.

In addition, the focusing element 58 may be configured by combining a plurality of optical elements for the purpose of suppressing aberration or the like. For example, a convex lens that focuses light and a concave lens that diffuses light may be combined to configure the focusing element 58 that focuses light as in a convex lens as a whole.

In the exposure device 50 in the example shown in the drawing, the focusing element 58 is disposed on the optical path of the first light M1 transmitted through the first surface 60a of the beam combiner element 60. However, the present invention is not limited thereto.

That is, in the exposure device according to the embodiment of the present invention, the focusing element 58 may be disposed on the optical path of the second light M2 reflected from the second surface 60b of the beam combiner element 60. In this case, the first light M1 is linearly polarized light of a plane wave (parallel light) having no spread, and the second light M2 is linearly polarized light of a spherical wave having a spread.

Accordingly, in this case, the light shielding member 64, which will be described below, shields a part of the first light M1 of the plane wave that does not transmit through the focusing element 58. In addition, the polarizer 68 shields a part of the second light M2, which is a spherical wave focused by the focusing element 58 and has a spread.

By the way, the first light M1 is focused by the focusing element 58 and spreads after the focal point. That is, a part of the first light M1 emitted from the beam combiner element 60 has an angle with respect to the optical axis.

As the angle of the first light M1 increases, the interference pattern formed on the photosensitive material Z is fine. Specifically, in a case where a direction perpendicular to a main surface of the photosensitive material Z, that is, the normal direction is set to 0°, as the angle at which the first light M1 is incident into the photosensitive material Z increases, a fine interference pattern can be obtained. That is, as the angle at which the first light M1 is incident into the photosensitive material Z is wider, a fine interference pattern is formed on the photosensitive material Z.

The interference pattern by the exposure device 50 is an interference pattern in which the short lines change while continuously rotating in the one direction as shown in FIG. 2. In this interference pattern, as the angle of incidence of the first light M1 into the photosensitive material Z increases, the single period A over which the short line rotates by 180° in the above-described one direction (the direction of the arrow) decreases.

That is, the single period A, in other words, the fineness of the interference pattern can be adjusted by the focal length, that is, the focusing power of the focusing element 58.

The main surface is the maximum surface of a sheet-shaped material (a film, a layer, or a plate-shaped material).

As described above, the exposure device 50 combines the first light M1, which is the linearly polarized light focused by the focusing element 58, and the second light M2, which is the linearly polarized light of the straight light that does not transmit through the focusing element 108, to expose the photosensitive material Z to the interference light. The first light M1 and the second light M2 are linearly polarized lights orthogonal to each other.

That is, the exposure device 50 performs the interference exposure by combining linearly polarized light of a plane wave (parallel light) having no spread and linearly polarized light of a spherical wave having a spread to convert the linearly polarized lights into circularly polarized lights having opposite turning directions, thereby forming the above-described interference pattern.

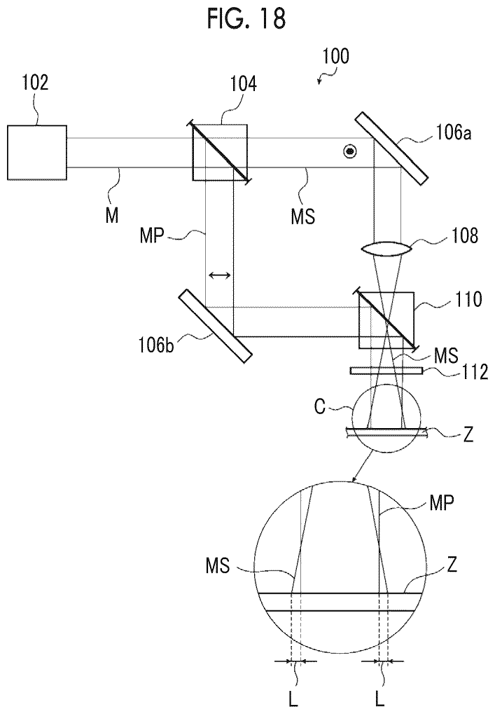

Here, in the exposure device in the related art, such as described in “Fabrication of ideal geometric-phase holograms with arbitrary wavefronts”, Optica Vol. 2, No. 11, November 2015, pp. 958-964, in which interference exposure is performed by interfering light in which one is a spherical wave and the other is a plane wave, as described above, in the photosensitive material Z, an effective region exposed to the interference light and a non-interference exposure region exposed only to the spherical wave are generated, and there is a problem that this non-interference exposure region is wasted (refer to FIG. 18).

On the other hand, the exposure device according to the embodiment of the present invention includes the light shielding member 64 that shields a part of the first light M1 which is the spherical wave focused by the focusing element 58 and the polarizer 68 that shields a part of the second light which is the plane wave not focused by the focusing element 58. The exposure device according to the embodiment of the present invention has such a configuration, and thus, it is possible to suppress the occurrence of a non-interference exposure region exposed only to a spherical wave and to use the photosensitive material Z without waste.

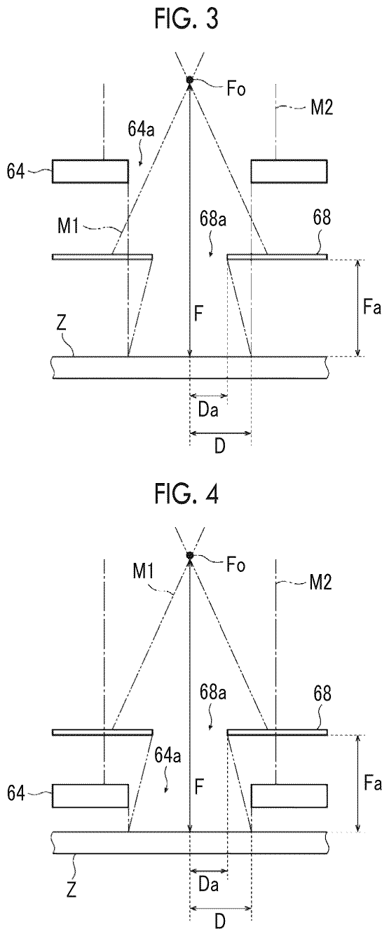

Hereinafter, the description will be made with reference to the conceptual diagram shown in FIG. 3.

FIG. 3 conceptually shows a downstream side of the focusing element 58 from the focal point Fo in the exposure device 50. In the present invention, the upstream and the downstream are upstream and downstream of the traveling direction of the light emitted from the light source 52.

Here, in FIG. 3, the beam combiner element 60 and the polarization conversion element 62 are omitted in order to simplify the drawing and to make the configuration and the action of the exposure device 50 easy to understand. In the exposure device 50, as shown in FIG. 1, the beam combiner element 60 is disposed between the focusing element 58 and the light shielding member 64, and the polarization conversion element 62 is disposed between the polarizer 68 and the photosensitive material Z.

Regarding this point, the same can also be applied to the example shown in FIGS. 4 to 7 described below. In FIG. 6, the polarization conversion element 62 is shown.

In the exposure device 50, the light shielding member 64 and the polarizer 68 are disposed in the order of the light shielding member 64 and the polarizer 68 downstream of the focal point Fo of the focusing element 58 toward the downstream.

The light shielding member 64 shields a part of the second light M2 which is linearly polarized light of a plane wave that is not focused by the focusing element 58. Specifically, the light shielding member 64 is a well-known light shielding member that restricts a light irradiation region by having an opening 64a through which light is transmitted, and is a light shielding member having a so-called aperture.

Here, the opening 64a may be a hole (through-hole) formed so that there is no physical obstruction to light, or may be formed of a material that is optically transparent to light having a wavelength that is shielded by the light shielding member 64. In the latter case, the transmittance of light in the opening 64a is 80% or more, preferably 90% or more, and more preferably 95% or more.

In the present invention, the light shielding member is not limited to shielding only the light that is not focused by the focusing element 58. That is, in the present invention, in a case where the light shielding member shields a part of the light that is not focused by the focusing element 58, for example, as shown in FIG. 6 described below, the light shielding member may shield a part of the light (first light M1) of the spherical wave focused by the focusing element 58 at the same time.

In addition, in the present invention, a polarizer (linear polarizer) that shields linearly polarized light of a plane wave and allows transmission of linearly polarized light of a spherical wave can also be used as the light shielding member. That is, in the present invention, the light shielding member also includes a light shielding member formed of a polarizer that shields the linearly polarized light not transmitted through the focusing element.

On the other hand, the polarizer 68 is a polarizer (linear polarizer) that shields a part of the first light M1, which is linearly polarized light of a spherical wave focused by the focusing element 58. That is, the polarizer 68 is a polarizer having an opening 68a through which the first light M1 transmits.

As described above, the first light M1 and the second light M2 are linearly polarized lights orthogonal to each other. In the example shown in the drawing, the first light M1 is the S-polarized light, and the second light M2 is the P-polarized light. That is, the polarizer 68 is a polarizer that shields the first light M1 which is linearly polarized light and allows transmission of the second light M2 which is linearly polarized light in a direction orthogonal to the first light M1.

In the present invention, the shape of the opening 64a of the light shielding member 64 and the shape of the opening 68a of the polarizer 68 are not limited.

However, it is preferable that the shape of the opening 64a of the light shielding member 64 and the shape of the opening 68a of the polarizer 68 are the same shape such as a square shape, a rectangular shape, a hexagonal shape, a circular shape, and an elliptical shape. For example, in a case where it is desired to form an interference pattern (diffractive optical element described below) in a rectangular planar shape, it is preferable that the shapes of the opening 64a of the light shielding member 64 and the opening 68a of the polarizer 68 are rectangular. In addition, in a case where it is desired to form the interference pattern in a circular planar shape, it is preferable that the shapes of the opening 64a of the light shielding member 64 and the opening 68a of the polarizer 68 are circular. The planar shape of the interference pattern is, in other words, the shape of the photosensitive material Z in the plane direction.

However, regardless of the shape of the opening 64a of the light shielding member 64 and the opening 68a of the polarizer 68, that is, the planar shape of the interference pattern, the interference pattern (alignment pattern) formed in the photosensitive material Z is the above-described concentric circular interference pattern.

As described above, the first light M1 is linearly polarized light of a spherical wave that is focused by the focusing element 58, and has a spread downstream of the focal point Fo of the focusing element 58.

On the other hand, the second light M2 is parallel light that is linearly polarized light of a plane wave that does not transmit through the focusing element 58 and does not have a spread.

In the exposure device 50, the first light M1 and the second light M2 that are combined are incident on the light shielding member 64 downstream of the focal point Fo. In the combined first light M1 and second light M2, a region incident into the opening of the light shielding member 64 is transmitted, and a region incident into a portion other than the opening 64a is shielded.

In the exposure device 50, the second light M2, which is a plane wave, transmits through a region where the light is incident on the opening 64a, and a region where the light is incident on a portion other than the opening 64a is shielded by the light shielding member 64. That is, the second light M2 is restricted by the light shielding member 64 in the irradiation region of the photosensitive material Z.

On the other hand, the first light M1 that is a spherical wave does not spread to the outside of the opening 64a of the light shielding member 64 and is transmitted through the light shielding member 64 as it is. In the present invention, as described above, a part of the spherical wave focused by the focusing element 58 may be shielded by the light shielding member.

The combined first light M1 and second light M2 transmitted through the light shielding member 64 are then incident into the polarizer 68 having the opening 68a.

As described above, the polarizer 68 is a linear polarizer that shields the first light M1 and allows transmission of the second light M2 that is linearly polarized light orthogonal to the first light M1. Accordingly, even in a case where the second light M2 is incident on a portion other than the opening 68a of the polarizer 68, the second light M2 is transmitted as it is.

On the other hand, the first light M1 transmits a region where the light is incident on the opening 68a of the polarizer 68, and shields a region where the light is incident on a portion other than the opening 68a of the polarizer 68. That is, the first light M1 which is a spherical wave and has a spread is restricted by the polarizer 68 in the irradiation region of the photosensitive material Z.

The combined first light M1 and second light M2 transmitted through the polarizer 68 are then converted into circularly polarized lights having opposite turning directions by the polarization conversion element 62 (refer to FIG. 1) as described above. In FIG. 3, the polarization conversion element 62 is omitted.

As described above, the circularly polarized lights of the combined first light M1 and second light M2 having opposite turning directions are incident into the photosensitive material Z, and the photosensitive material Z is subjected to interference exposure to form the interference pattern shown in FIG. 2.

As described above, the exposure device 50 according to the embodiment of the present invention is an exposure device that performs interference exposure using circularly polarized lights having opposite turning directions after the first light M1 that is linearly polarized light of a spherical wave focused by the focusing element and the second light M2 that is linearly polarized light orthogonal in a plane wave are combined and converted into circularly polarized light.

In the exposure device according to the embodiment of the present invention, the light shielding member that shields a part of the plane wave and the polarizer that shields a part of the spherical wave are used, so that the irradiation regions of the first light M1 and the second light M2 in the photosensitive material Z can be independently restricted in consideration of the spread of the first light M1 which is the spherical wave.

Therefore, with the exposure device 50 according to the embodiment of the present invention, it is possible to suppress a non-interference exposure region exposed only to a spherical wave and to use the photosensitive material Z without waste, similarly to the exposure device in the related art as shown in “Fabrication of ideal geometric-phase holograms with arbitrary wavefronts”, Optica Vol. 2, No. 11, November 2015, pp. 958-964.

Here, in the exposure device 50 according to the embodiment of the present invention,
it is preferable that, in a case where
a distance from the optical axis of the focusing element 58 to the light shielding member 64 is denoted by D,
a distance from the optical axis of the focusing element 58 to the polarizer 68 is denoted by Da,
a distance from the focal point Fo of the focusing element 58 to the photosensitive material Z (exposure target) is denoted by F, and
a distance from the polarizer 68 to the photosensitive material Z (exposure target) is denoted by Fa,

Da=D×(F−Fa)/F is satisfied.

In a case where the exposure device 50 satisfies the above-described expression, the exposure region by the first light M1, which is a spherical wave transmitted through the focusing element 58, and the exposure region by the second light M2, which is a plane wave not transmitted through the focusing element 58, in the photosensitive material Z can be made to substantially match each other.

That is, in a case where the exposure device 50 satisfies the above-described expression, the non-interference exposure region exposed only to the first light M1, which is a spherical wave, can be made extremely small or almost eliminated.

In the exposure device 50 shown in FIGS. 1 and 3, the light shielding member 64 and the polarizer 68 are disposed in this order toward the downstream, but the present invention is not limited thereto.

That is, in the exposure device according to the embodiment of the present invention, as conceptually shown in FIG. 4, the polarizer 68 may be disposed upstream, and the light shielding member 64 may be disposed downstream.

In this configuration, as shown in FIG. 4, the first light M1 and the second light M2 that are combined by the beam combiner element 60 are first incident into the polarizer 68.

As described above, the polarizer 68 is a polarizer that shields the first light M1 which is a spherical wave and allows transmission of the second light M2 which is a plane wave with linearly polarized light orthogonal to the first light M1. Therefore, in the polarizer 68, as shown in FIG. 4, the second light M2 transmits through all regions, the first light M1 only transmits through a region incident into the opening 68a of the polarizer 68, and a region incident into a portion other than the opening 68a is shielded.

The combined first light M1 and second light M2 are then incident into the light shielding member 64. The second light M2 that is a plane wave and is not completely shielded by the polarizer 68 transmits through a region where the light is incident on the opening 64a, and a region where the light is incident on a portion other than the opening 64a is shielded by the light shielding member 64. On the other hand, the first light M1 has a spherical wave and has a spread, but since a part of the first light M1 is shielded by the polarizer 68 in advance, the entire region of the first light M1 transmits through the opening 64a of the light shielding member 64 as shown in FIG. 4.

As in the above-described example, the combined first light M1 and second light M2 transmitted through the light shielding member 64 are converted into circularly polarized lights having opposite turning directions by the polarization conversion element 62 (not shown in FIG. 4), are incident into the photosensitive material Z, and the photosensitive material Z is subjected to interference exposure to form the interference pattern shown in FIG. 2.

That is, in the exposure device according to the embodiment of the present invention, even in a case where the polarizer 68 and the light shielding member 64 are disposed in this order toward the downstream as shown in FIG. 4 downstream of the beam combiner element 60, it is possible to suppress the occurrence of a non-interference exposure region that is exposed only to the spherical wave by independently restricting the irradiation regions of the first light M1 and the second light M2 in the photosensitive material Z.

In particular, by satisfying the above-described expression “Da=D×(F−Fa)/F”, it is possible to substantially eliminate the non-interference exposure region.

In the exposure device according to the embodiment of the present invention, the positional relationship between the polarizer 68 and the light shielding member 64 in the traveling direction of light is not limited.

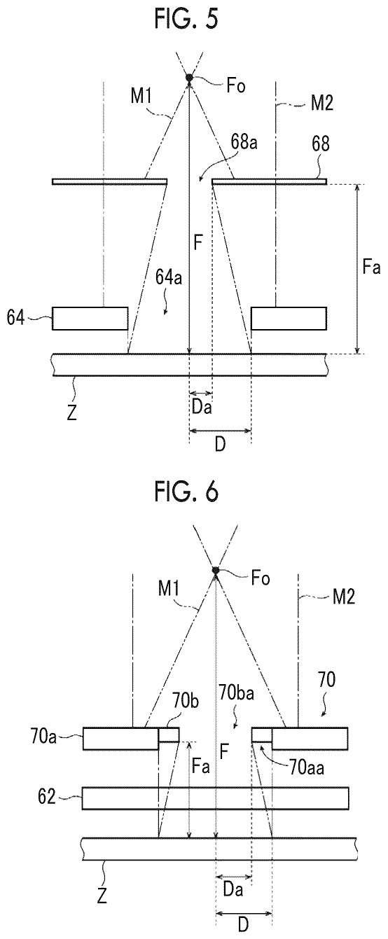

For example, in the configuration shown in FIG. 4, as conceptually shown in FIG. 5, the polarizer 68 and the light shielding member 64 may be extremely spaced apart from each other. Even with such a configuration, with the exposure device according to the embodiment of the present invention, the irradiation regions of the first light M1 and the second light M2 in the photosensitive material Z can be independently restricted, and the non-interference exposure region can be suppressed. In particular, by satisfying the expression “Da=D×(F−Fa)/F”, it is possible to substantially eliminate the non-interference exposure region.

In the above-described example, the polarizer 68 and the light shielding member 64 are disposed at different positions in the traveling direction of the first light M1 and the second light M2 combined by the beam combiner element 60, but the present invention is not limited thereto.

For example, in the exposure device according to the embodiment of the present invention, as conceptually shown in FIG. 6, a light control member 70 in which a light shielding member and a polarizer are combined may be used.

The light control member 70 is obtained by incorporating a polarizer 70b having an opening 70ba into an opening 70aa provided in a light shielding member 70a. In addition, in the light control member 70, the edge of the opening 70aa of the light shielding member 70a and the outer edge of the polarizer 70b match each other. That is, in the light control member, the light shielding member and the polarizer are disposed at the same position in the traveling direction of the first light M1 and the second light M2 that are combined by the beam combiner element 60.

In the present example, the first light M1 and the second light M2 that are combined by the beam combiner element 60 are incident into the light control member 70, a region where the light is incident into the opening 70aa of the light shielding member 70a transmits, and a region where the light is incident into a portion other than the opening 70aa is shielded.

The combined first light M1 and second light M2 are also incident into the polarizer 70b at the same time. As in the above example, the polarizer 70b is a linear polarizer that shields the first light M1 which is linearly polarized light of a spherical wave and has a spread and allows transmission of the second light M2 which is a plane wave and linearly polarized light orthogonal to the first light M1. Accordingly, in the first light M1 and the second light M2, the entire region of the second light M2 transmits through the polarizer 70b, and the first light M1 which is a spherical wave transmits through the region, which is incident into the opening 70ba of the polarizer 70b and shields the region, which is incident into a portion other than the opening 70ba.

Therefore, also in the present example, the irradiation regions of the first light M1 and the second light M2 in the photosensitive material Z can be independently restricted to suppress the non-interference exposure region. In particular, even in the present example, by satisfying the expression “Da=D×(F−Fa)/F”, it is possible to substantially eliminate the non-interference exposure region.

In all of the above-described exposure devices, the light shielding member 64 and the polarizer 68 (light control member 70) are disposed between the beam combiner element 60 and the polarization conversion element 62.

However, the exposure device according to the embodiment of the present invention is not limited thereto, and the light shielding member 64 may be disposed downstream of the polarization conversion element 62. That is, in the exposure device according to the embodiment of the present invention, the light shielding member 64 may be disposed on the optical path of the first light M1 and the second light M2 combined by the beam combiner element 60.

However, in the exposure device according to the embodiment of the present invention, the polarizer 68 is necessary to be disposed between the beam combiner element 60 and the polarization conversion element 62.

In addition, in all of the above-described exposure devices, the opening 64a, that is, the transmissive region of the light shielding member 64 is wider than the opening 68a of the polarizer 68, that is, the transmissive region. That is, in the above-described example, in the distance D from the optical axis of the focusing element 58 to the light shielding member 64 and the distance Da from the optical axis of the focusing element 58 to the polarizer 68, “Da<D” is satisfied.

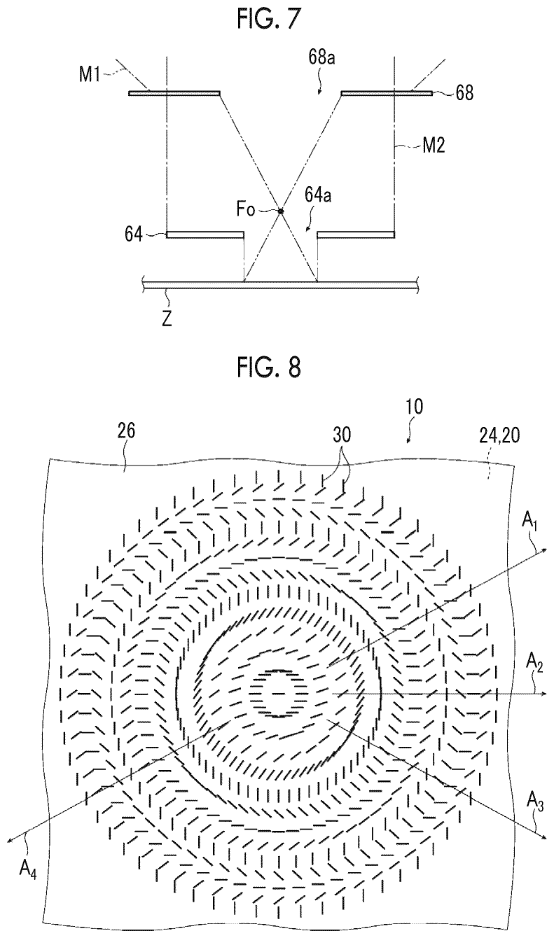

However, the exposure device according to the embodiment of the present invention is not limited thereto. For example, as conceptually shown in FIG. 7, a configuration can also be adopted in which the opening 68a of the polarizer 68 is made larger than the opening 64a of the light shielding member 64 (“Da>D”), the polarizer 68 is disposed upstream of the focal point Fo of the focusing element 58, and the light shielding member 64 is disposed downstream of the focal point Fo.

Here, at the edge of the opening 68a of the polarizer 68, a part of the first light M1, which is a spherical wave, or further, a part of the second light M2, which is a plane wave, is diffracted. The diffracted light may be stray light and affect the exposure of the photosensitive material Z (exposure target).

Here, the influence of the diffraction by the polarizer 68 is larger as the opening 68a is smaller, that is, as the transmissive region is narrower. In addition, the influence of the diffraction by the polarizer 68 is larger as the distance between the polarizer 68 and the photosensitive material Z is longer.

In consideration of this point, it is preferable that the polarizer 68 is disposed as close to the photosensitive material Z as possible. Specifically, the distance between the polarizer 68 and the photosensitive material Z is preferably about 1 to 15 mm, and more preferably 1 to 5 mm in order to reduce the influence of diffraction of light at the end part of the opening 64a of the light shielding member 64.

In consideration of this point, it is preferable that the polarizer 68 is disposed downstream of the focal point of the focusing element 58.

Therefore, in the present invention, it is preferable that the opening 64a of the light shielding member 64, that is, the transmissive region is larger than the opening 68a of the polarizer 68, that is, the transmissive region, and it is preferable that “Da<D” is satisfied.

As described above, with the exposure device 50 according to the embodiment of the present invention, in the photosensitive material Z, the non-interference exposure region exposed only to the first light M1, which is a spherical wave having a spread transmitted through the focusing element 58, can be suppressed.

The method of manufacturing a diffractive optical element according to the embodiment of the present invention is a method of manufacturing a diffractive optical element using the above-described exposure device according to the embodiment of the present invention. The method of manufacturing a diffractive optical element according to the embodiment of the present invention includes an exposure step of exposing an alignment film including a compound having a photo-aligned group using the exposure device according to the embodiment of the present invention, and a film forming step of applying a composition including a liquid crystal compound to the exposed alignment film and drying the composition.

In the following description, the method of manufacturing the diffractive optical element according to the embodiment of the present invention will also be referred to as the manufacturing method according to the embodiment of the present invention.

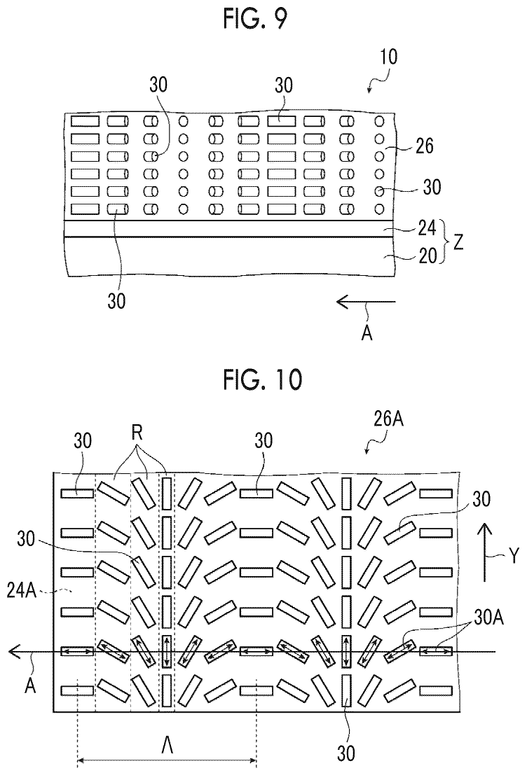

In the manufacturing method according to the embodiment of the present invention, for example, as conceptually shown in FIG. 9 described below, on a support 20, a photosensitive material Z having an alignment film 24 consisting of a photo-alignment film is used, and first, in the exposure step, the photosensitive material Z is subjected to interference exposure using the exposure device 50 according to the embodiment of the present invention to form an interference pattern. After that, the method of manufacturing a diffractive optical element (liquid crystal diffraction element) by applying a composition including a liquid crystal compound and drying the composition in the film forming step is exemplified.

As the support 20, various sheet-shaped materials (films or plate-shaped materials) can be used as long as they can support the alignment film 24 and an optically-anisotropic layer 26 described below.

As the support 20, a transparent support is preferable, and examples thereof include a polyacrylic resin film such as polymethyl methacrylate, a cellulose-based resin film such as cellulose triacetate, a cycloolefin polymer-based film, polyethylene terephthalate (PET), polycarbonate, and polyvinyl chloride. The support is not limited to a flexible film and may be a non-flexible substrate such as a glass substrate. Examples of the cycloolefin polymer-based film include “ARTON” (trade name) manufactured by JSR Corporation and “ZEONOR” (trade name) manufactured by Nippon Zeon Corporation.

A coating film including a compound having a photo-aligned group is formed on a surface of the support 20, and this coating film is dried.

Thereafter, the dried coating film is irradiated with the interference light in which the first light M1 and the second light M2 of circularly polarized light are combined by the exposure device 50 according to the embodiment of the present invention. As a result, the interference pattern is formed on the coating film, and the alignment film 24 having the alignment pattern is formed (exposure step).

As described above, with the exposure device 50, the alignment film 24 having the same alignment pattern as the interference pattern having the pattern in which the short line (short straight line) changes while continuously rotating in one direction in a radial shape as shown in FIG. 2 can be formed.

Preferable examples of the compound having a photo-aligned group that is, the photo-alignment material used in the photo-alignment film that can be used in the present invention include: an azo compound described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; an aromatic ester compound described in JP2002-229039A; a maleimide- and/or alkenyl-substituted nadiimide compound having a photo-alignable unit described in JP2002-265541A and JP2002-317013A; a photocrosslinking silane derivative described in JP4205195B and JP4205198B, a photocrosslinking polyimide, a photocrosslinking polyamide, or a photocrosslinking ester described in JP2003-520878A, JP2004-529220A, and JP4162850B; and a photodimerizable compound, in particular, a cinnamate (cinnamic acid) compound, a chalcone compound, or a coumarin compound described in JP1997-118717A (JP-H9-118717A), JP1998-506420A (JP-H10-506420A), JP2003-505561A, WO2010/150748A, JP2013-177561A, and JP2014-12823A.

Among these, an azo compound, a photocrosslinking polyimide, a photocrosslinking polyamide, a photocrosslinking ester, a cinnamate compound, or a chalcone compound is suitably used.

Here, in the manufacturing method according to the embodiment of the present invention, in the exposure of the alignment film 24 using the exposure device 50, that is, in the exposure step, it is preferable that the exposure of the alignment film 24 is performed, and then the alignment film 24 and the exposure device 50 are relatively moved in the plane direction of the alignment film 24, and the exposure is repeatedly performed again at another position of the alignment film 24 a plurality of times.

That is, in the manufacturing method according to the embodiment of the present invention, it is preferable that the exposure by the exposure device 50 and the relative movement between the alignment film 24 and the exposure device 50 are repeatedly performed using the alignment film 24 (photosensitive material Z) capable of forming a plurality of diffractive optical elements.

Accordingly, it is preferable that the exposure device according to the embodiment of the present invention includes a support member of the photosensitive material Z (exposure target) and further includes a moving unit that relatively moves the support member and the exposure device 50.

The support member is not limited, and various well-known support members of sheet-shaped materials such as a support base can be used. The support member may have a fixing unit for the photosensitive material Z using suction, a magnetic force, static electricity, a jig, or the like.

In addition, the moving unit that relatively moves the support member and the exposure device 50 may be a unit that moves the support member, a unit that moves the exposure device 50 in an integrated manner, that is, in a unitized manner, or a unit that moves both the support member and the exposure device 50. The moving unit of the support member is not limited, and various well-known moving units of support members of sheet-shaped materials can be used. In addition, the moving unit of the exposure device 50 is not limited, and various well-known moving units of optical devices (optical units) can be used. Further, a method of integrating the members constituting the exposure device 50, that is, unitizing the exposure device 50 is not limited, and various well-known methods can be used.

In the manufacturing method according to the embodiment of the present invention, a composition including a liquid crystal compound is applied to the alignment film formed as described above and is dried, and the liquid crystal compound is optionally cured.

FIGS. 8 and 9 conceptually show an example of the diffractive optical element manufactured using the manufacturing method according to the embodiment of the present invention. FIG. 8 is a plan view conceptually showing the diffractive optical element, and FIG. 9 is a cross-sectional view conceptually showing the diffractive optical element. The plan view is a view of the diffractive optical element as viewed from the thickness direction. In other words, the thickness direction is a laminating direction of the respective layers (films).

As described above, the alignment film 24 is formed on the support 20. The diffractive optical element 10 shown in FIGS. 8 and 9 includes the optically-anisotropic layer 26 that is formed on the alignment film 24 using the composition including a liquid crystal compound. The diffractive optical element 10 is a liquid crystal diffraction element and acts as, for example, a transmissive-type liquid crystal diffractive lens.

In the following description, the diffractive optical element 10 will also be referred to as the optical element 10.

As described above, the alignment film 24 has the interference pattern in which the orientation of the short line changes while continuously rotating in the one direction in a radial shape from the inner side toward the outer side.

The optically-anisotropic layer 26 that is formed on the alignment film 24 using the composition including a liquid crystal compound includes a liquid crystal alignment pattern in which an orientation of an optical axis derived from a liquid crystal compound 30 changes while continuously rotating in one direction in a radial shape from the inner side toward the outer side. That is, the liquid crystal alignment pattern in the optically-anisotropic layer 26 shown in FIGS. 8 and 9 is a concentric circular pattern having the one direction in which the orientation of the optical axis derived from the liquid crystal compound 30 changes while continuously rotating in a concentric circular shape from the inner side toward the outer side.

In FIGS. 8 to 12, for example, a rod-like liquid crystal compound is used as the liquid crystal compound 30. Therefore, the direction of the optical axis matches a longitudinal direction of the liquid crystal compound 30.

In the optically-anisotropic layer 26, the orientation of the optical axis of the liquid crystal compound 30 changes while continuously rotating in a plurality of directions from the center toward the outer side of the optically-anisotropic layer 26, for example, a direction indicated by an arrow A₁, a direction indicated by an arrow A₂, a direction indicated by an arrow A₃, a direction indicated by an arrow A₄, or . . . .

Accordingly, in the optically-anisotropic layer 26, the rotation direction of the optical axis of the liquid crystal compound 30 is the same as all the directions (one direction). In the example shown in the drawing, in all the directions including the direction indicated by the arrow A₁, the direction indicated by the arrow A₂, the direction indicated by the arrow A₃, and the direction indicated by the arrow A₄, the rotation direction of the optical axis of the liquid crystal compound 30 is counterclockwise.

That is, in a case where the arrow A₁ and the arrow A₄ are assumed as one straight line, the rotation direction of the optical axis of the liquid crystal compound 30 is reversed at the center of the optically-anisotropic layer 26 on the straight line. For example, the straight line formed by the arrow A₁ and the arrow A₄ is directed in the right direction (arrow A1 direction) in the drawing. In this case, the optical axis of the liquid crystal compound 30 initially rotates clockwise from the outer side to the center of the optically-anisotropic layer 26, the rotation direction is reversed at the center of the optically-anisotropic layer 26, and then the optical axis of the liquid crystal compound 30 rotates counterclockwise from the center to the outer side of the optically-anisotropic layer 26.

In addition, in the optically-anisotropic layer 26 of the optical element 10, in the liquid crystal alignment pattern, in a case where a length over which the orientation of the optical axis derived from the liquid crystal compound rotates by 180° in the one direction in which the orientation of the optical axis of the liquid crystal compound 30 changes while continuously rotating is set as a single period, the length of the single period gradually decreases from the inner side toward the outer side.

In circularly polarized light incident into the optically-anisotropic layer 26 having the above-described liquid crystal alignment pattern, an absolute phase changes depending on individual local regions having different orientations of optical axes of the liquid crystal compound 30. In this case, the amount of change in absolute phase in each of the local regions varies depending on the orientations of the optical axes of the liquid crystal compound 30 into which circularly polarized light is incident.

In the optically-anisotropic layer (optical element 10) having the liquid crystal alignment pattern in which the orientation of the optical axis of the liquid crystal compound 30 changes while continuously rotating in the one direction, a refraction direction of transmitted light depends on the rotation direction of the optical axis of the liquid crystal compound 30. That is, in this liquid crystal alignment pattern, in a case where the rotation direction of the optical axis of the liquid crystal compound 30 is reversed, the refraction direction of transmitted light is also reversed with respect to the one direction in which the optical axis rotates.

In addition, the diffraction angle of the optically-anisotropic layer 26 increases as the single period decreases. That is, the diffraction of light of the optically-anisotropic layer 26 increases as the single period decreases.

As described above, the single period can be adjusted by the focal length, that is, the lens power of the focusing element 58 of the exposure device 50.

Accordingly, in the optically-anisotropic layer 26 having the concentric circular liquid crystal alignment pattern, that is, the liquid crystal alignment pattern in which the optical axis changes while continuously rotating in a radial shape, incidence light (light beam) can be diffused or be focused and transmitted depending on the rotation direction of the optical axis of the liquid crystal compound 30 and the turning direction of circularly polarized light to be incident.

The optically-anisotropic layer 26 is formed of a composition including a liquid crystal compound.

In FIG. 8 and FIGS. 10 and 12 described below, in order to simplify the drawing and to clarify the configuration of the optical element 10, only the liquid crystal compound 30 (liquid crystal compound molecules) on the surface of the alignment film 24 in the optically-anisotropic layer 26 is shown. However, as conceptually shown in FIG. 9, the optically-anisotropic layer 26 has a structure in which the aligned liquid crystal compounds 30 are laminated as in an optically-anisotropic layer that is formed using a composition including a typical liquid crystal compound.

In a case where an in-plane retardation value is set as λ/2, the optically-anisotropic layer 26 has a function of a general λ/2 plate, that is, a function of imparting a retardation of a half wavelength, that is, 180° to two linearly polarized light components in light incident into the optically-anisotropic layer and are orthogonal to each other. In other words, the in-plane retardation is a retardation in a plane direction.

In a plane of the optically-anisotropic layer, the optically-anisotropic layer 26 includes the liquid crystal alignment pattern in which the orientation of the optical axis derived from the liquid crystal compound changes while continuously rotating in one direction (for example, directions of the arrow A₁ to the arrow A₄ in FIG. 1) in a radial shape from the inner side toward the outer side.

The optical axis 30A derived from the liquid crystal compound 30 is an axis having the highest refractive index in the liquid crystal compound 30, that is, a so-called slow axis. For example, in a case where the liquid crystal compound 30 is a rod-like liquid crystal compound, the optical axis 30A is along a rod-like major axis direction.

In the following description, the optical axis 30A derived from the liquid crystal compound 30 will also be referred to as “the optical axis 30A of the liquid crystal compound 30” or “the optical axis 30A”.

Hereinafter, the optically-anisotropic layer 26 will be described with reference to an optically-anisotropic layer 26A that includes a liquid crystal alignment pattern in which the optical axes 30A change while continuously rotating in one direction indicated by an arrow A as conceptually shown in a plan view of FIG. 10.

Even in the liquid crystal alignment pattern shown in FIG. 8 that includes one direction in which the optical axis changes while continuously rotating in a concentric circular shape (radial shape) from the inner side toward the outer side, the same optical effects as those of the liquid crystal alignment pattern shown in FIG. 10 can be exhibited for the one direction in which the optical axis changes while continuously rotating.

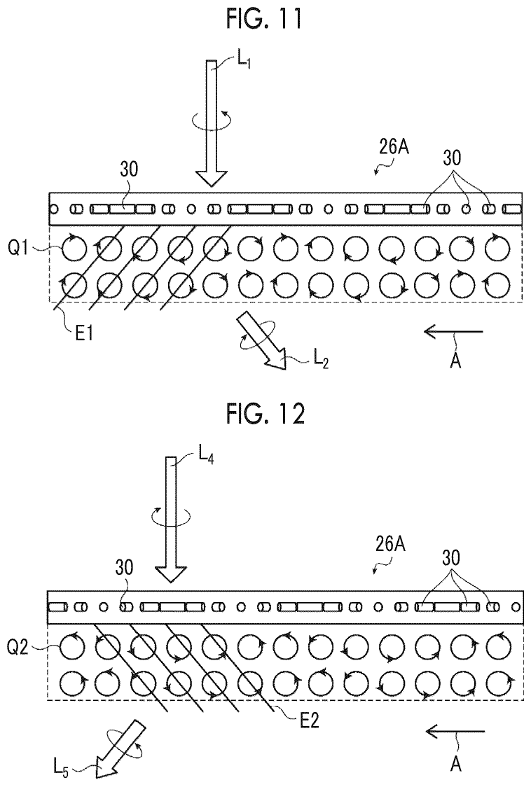

In the optically-anisotropic layer 26A, the liquid crystal compound 30 is two-dimensionally arranged in a plane parallel to the one direction indicated by the arrow A and a Y direction orthogonal to the arrow A direction. In FIGS. 11 and 12 described below, the Y direction is a direction orthogonal to the paper plane.

In the following description, “one direction indicated by the arrow A” will also be simply referred to as “arrow A direction”.

In the optically-anisotropic layer 26 shown in FIG. 8, a circumferential direction of a concentric circle in the concentric circular liquid crystal alignment pattern corresponds to the Y direction in FIG. 10.

The optically-anisotropic layer 26A has the liquid crystal alignment pattern in which the orientation of the optical axis 30A derived from the liquid crystal compound 30 changes while continuously rotating in the arrow A direction in a plane of the optically-anisotropic layer 26A.

Specifically, “the orientation of the optical axis 30A of the liquid crystal compound 30 changes while continuously rotating in the arrow A direction (the predetermined one direction)” represents that an angle between the optical axis 30A of the liquid crystal compound 30, which is arranged in the arrow A direction, and the arrow A direction varies depending on positions in the arrow A direction, and the angle between the optical axis 30A and the arrow A direction sequentially changes from θ to θ+180° or θ−180° in the arrow A direction.

A difference between the angles of the optical axes 30A of the liquid crystal compound 30 adjacent to each other in the arrow A direction is preferably 45° or less, more preferably 15° or less, and still more preferably less than 15°.

On the other hand, regarding the liquid crystal compound 30 forming the optically-anisotropic layer 26A, the liquid crystal compounds 30 having the same orientation of the optical axes 30A are arranged at regular intervals in the Y direction orthogonal to the arrow A direction, that is, the Y direction orthogonal to the one direction in which the optical axis 30A continuously rotates.

In other words, regarding the liquid crystal compound 30 forming the optically-anisotropic layer 26, in the liquid crystal compounds 30 arranged in the Y direction, angles between the orientations of the optical axes 30A and the arrow A direction are the same.

In the optically-anisotropic layer 26 shown in FIG. 8, a region where the orientations of the optical axes 30A are the same is formed in an annular shape where the centers match with each other.

As in the above-described short line, even in the optically-anisotropic layer 26, in the liquid crystal alignment pattern in which the optical axis 30A continuously rotates in the one direction, a length (distance) over which the optical axis 30A of the liquid crystal compound 30 rotates by 180° is set as a length A of the single period in the liquid crystal alignment pattern.

That is, in the optically-anisotropic layer 26A shown in FIG. 10, the length (distance) over which the optical axis 30A of the liquid crystal compound 30 rotates by 180° in the arrow A direction in which the orientation of the optical axis 30A changes while continuously rotating in a plane is set as the single period A in the liquid crystal alignment pattern. In other words, the single period A in the liquid crystal alignment pattern is defined by the distance between θ and θ+180° that is a range of the angle between the optical axis 30A of the liquid crystal compound 30 and the arrow A direction.

That is, a distance between centers of two liquid crystal compounds 30 in the arrow A direction is the single period A, the two liquid crystal compounds 30 having the same angle in the arrow A direction. Specifically, as shown in FIG. 10, a distance of centers in the arrow A direction of two liquid crystal compounds 30 in which the arrow A direction and the direction of the optical axis 30A match each other is the single period A.

In the optically-anisotropic layer 26A (optically-anisotropic layer 26), in the liquid crystal alignment pattern of the optically-anisotropic layer, the single period A is repeated in the arrow A direction, that is, in the one direction in which the orientation of the optical axis 30A changes while continuously rotating.

In the optical element 10 having the liquid crystal alignment pattern in which the optical axis 30A continuously rotates in a concentric circular shape (radial shape), the single period A in the optically-anisotropic layer 26 gradually decreases from the inner side (center) toward the outer side.

In the liquid crystal compounds arranged in the Y direction in the optically-anisotropic layer 26A, the angles between the optical axes 30A and the arrow A direction are the same. Regions where the liquid crystal compounds 30 in which the angles between the optical axes 30A and the arrow A direction are the same are disposed in the Y direction will be referred to as “regions R”.

In this case, it is preferable that an in-plane retardation (Re) value of each of the regions R is a half wavelength, that is, λ/2. The in-plane retardation is calculated from the product of a difference An in refractive index generated by refractive index anisotropy of the region R and the thickness of the optically-anisotropic layer. Here, the difference in refractive index generated by refractive index anisotropy of the region R in the optically-anisotropic layer is defined by a difference between a refractive index of a direction of an in-plane slow axis of the region R and a refractive index of a direction orthogonal to the direction of the slow axis. That is, the difference An in refractive index generated by refractive index anisotropy of the region R is the same as a difference between a refractive index of the liquid crystal compound 30 in the direction of the optical axis 30A and a refractive index of the liquid crystal compound 30 in a direction perpendicular to the optical axis 30A in a plane of the region R. That is, the difference An in refractive index is the same as the difference in refractive index of the liquid crystal compound.

In the optical element 10 having the liquid crystal alignment pattern in which the optical axis 30A continuously rotates in the one direction in a radial shape, the region where the orientations of the optical axes 30A are the same that is formed in an annular shape where the centers match each other corresponds to the region R in FIG. 10. Regarding this point, the same can also be applied to the reflective-type diffractive optical element 36 including a cholesteric liquid crystal layer described below.

In a case where circularly polarized light is incident into the above-described optically-anisotropic layer 26A, the light is refracted such that the direction of the circularly polarized light is converted.

This action is conceptually shown in FIGS. 11 and 12. In the optically-anisotropic layer 26A, the value of the product of the difference in refractive index of the liquid crystal compound and the thickness of the optically-anisotropic layer is λ/2.

As described above, this action is also completely the same in the optical element 10 having the liquid crystal alignment pattern in which the optical axis 30A continuously rotates in the one direction in a radial shape.

As shown in FIG. 11, in a case where the value of the product of the difference in refractive index of the liquid crystal compound in the optically-anisotropic layer 26A and the thickness of the optically-anisotropic layer is λ/2 and incidence light L₁ as left circularly polarized light is incident into the optically-anisotropic layer 26A, the incidence light L₁ transmits through the optically-anisotropic layer 26A to be imparted with a retardation of 180°, and the transmitted light L₂ is converted into right circularly polarized light.

In addition, in a case where the incidence light L₁ transmits through the optically-anisotropic layer 26A, an absolute phase thereof changes depending on the orientation of the optical axis 30A of each of the liquid crystal compounds 30. In this case, the orientation of the optical axis 30A changes while rotating in the arrow A direction. Therefore, the amount of change in the absolute phase of the incidence light L₁ varies depending on the direction of the optical axis 30A. Further, the liquid crystal alignment pattern that is formed in the optically-anisotropic layer 26A is a pattern that is periodic in the arrow A direction. Therefore, as shown in FIG. 11, the incidence light L₁ transmitted through the optically-anisotropic layer 26A is imparted with an absolute phase Q1 that is periodic in the arrow A direction corresponding to the orientation of each of the optical axes 30A. As a result, an equiphase surface E1 that is tilted in a direction opposite to the arrow A direction is formed.

Therefore, the transmitted light L₂ is refracted (diffracted) to be tilted in a direction perpendicular to the equiphase surface E1 and travels in a direction different from a traveling direction of the incidence light L₁. This way, the incidence light L₁ of the left circularly polarized light is converted into the transmitted light L₂ of right circularly polarized light that is tilted by a predetermined angle in the arrow A direction with respect to an incidence direction.

On the other hand, as conceptually shown in FIG. 12, in a case where the value of the product of the difference in refractive index of the liquid crystal compound in the optically-anisotropic layer 26A and the thickness of the optically-anisotropic layer is λ/2 and incidence light L₄ as right circularly polarized light is incident into the optically-anisotropic layer 26A, the incidence light L₄ transmits through the optically-anisotropic layer 26A to be imparted with a retardation of 180° and is converted into transmitted light L₅ of left circularly polarized light.

In addition, in a case where the incidence light L₄ transmits through the optically-anisotropic layer 26A, an absolute phase thereof changes depending on the orientation of the optical axis 30A of each of the liquid crystal compounds 30. In this case, the orientation of the optical axis 30A changes while rotating in the arrow A direction. Therefore, the amount of change in the absolute phase of the incidence light L₄ varies depending on the direction of the optical axis 30A. Further, the liquid crystal alignment pattern that is formed in the optically-anisotropic layer 26A is a pattern that is periodic in the arrow A direction. Therefore, as shown in FIG. 9, the incidence light L₄ transmitted through the optically-anisotropic layer 26 is imparted with an absolute phase Q2 that is periodic in the arrow A direction corresponding to the orientation of each of the optical axes 30A.

Here, the incidence light L₄ is right circularly polarized light. Therefore, the absolute phase Q2 that is periodic in the arrow A direction corresponding to the orientation of the optical axis 30A is opposite to the incidence light L₁ as left circularly polarized light. As a result, in the incidence light L₄, an equiphase surface E2 that is tilted in the arrow A direction opposite to that of the incidence light L1 is formed.

Therefore, the incidence light L₄ is refracted to be tilted in a direction perpendicular to the equiphase surface E2 and travels in a direction different from a traveling direction of the incidence light L₄. This way, the incidence light L₄ is converted into the transmitted light L₅ of left circularly polarized light that is tilted by a predetermined angle in a direction opposite to the arrow A direction with respect to an incidence direction.

In the optically-anisotropic layer 26, it is preferable that the in-plane retardation value of the plurality of regions R is a half wavelength. It is preferable that an in-plane retardation Re(550)=Δn₅₅₀×d of the plurality of regions R of the optically-anisotropic layer 26 with respect to the incidence light having a wavelength of 550 nm is in a range defined by the following Expression (1). Here, Δn₅₅₀ represents a difference in refractive index generated by refractive index anisotropy of the region R in a case where the wavelength of incidence light is 550 nm, and d represents the thickness of the optically-anisotropic layer 26.

200 nm≤Δn₅₅₀×d≤350 nm (1)

The optically-anisotropic layer 26 functions as a so-called λ/2 plate. However, in the present invention, in a case where the support 20 and the alignment film 24 are provided, an aspect where a laminate integrally including the support 20 and the alignment film 24 functions as a λ/2 plate.

Here, by changing the single period A of the liquid crystal alignment pattern formed in the optically-anisotropic layer 26A, refraction angles of the transmitted lights L₂ and L₅ can be adjusted. Specifically, as the single period A of the liquid crystal alignment pattern decreases, lights transmitted through the liquid crystal compounds 30 adjacent to each other more strongly interfere with each other. Therefore, the transmitted lights L₂ and L₅ can be more largely refracted.

In addition, refraction angles of the transmitted lights L₂ and L₅ with respect to the incidence lights L₁ and L₄ vary depending on the wavelengths of the incidence lights L₁ and L₄ (the transmitted lights L₂ and L₅). Specifically, as the wavelength of incidence light increases, the transmitted light is largely refracted. That is, in a case where incidence light is red light, green light, and blue light, the red light is refracted to the highest degree, and the blue light is refracted to the lowest degree.

Further, by reversing the rotation direction of the optical axis 30A of the liquid crystal compound 30 that rotates in the arrow A direction, the refraction direction of transmitted light can be reversed.

As described above, in the optically-anisotropic layer 26 of the optical element 10, in the liquid crystal alignment pattern in which the optical axis 30A rotates in the one direction, the single period Λ of the liquid crystal alignment pattern gradually decreases from the inner side (center) toward the outer side.

Accordingly, depending on the wavelength, the polarization state, and the like of incident light, the rotation direction of the optical axis 30A from an inner side toward an outer side is set such that light is refracted from the center of the optical element 10, and the degree to which the length of the single period A of the liquid crystal alignment pattern gradually decreases is appropriately adjusted. As a result, the degree to which the light is focused toward the center (optical axis) of the optical element 10 can be adjusted.

That is, by increasing the degree to which the length of the single period A in the liquid crystal alignment pattern gradually decreases, the optical element 10 can act as a condenser lens (convex lens). In addition, by decreasing the degree to which the length of the single period A in the liquid crystal alignment pattern gradually decreases, the optical element 10 can act as a collimating lens.

The optically-anisotropic layer 26 is formed of a liquid crystal composition including a rod-like liquid crystal compound or a disk-like liquid crystal compound, and has a liquid crystal alignment pattern in which an optical axis of the rod-like liquid crystal compound or an optical axis of the disk-like liquid crystal compound is aligned as described above.

By forming the alignment film 24 having the alignment pattern corresponding to the above-described liquid crystal alignment pattern on the support 20 and applying the liquid crystal composition to the alignment film 24, and curing the applied liquid crystal composition, the optically-anisotropic layer consisting of the cured layer of the liquid crystal composition can be obtained.

In addition, the liquid crystal composition for forming the optically-anisotropic layer 26 includes a rod-like liquid crystal compound or a disk-like liquid crystal compound and may further include other components such as a leveling agent, an alignment control agent, a polymerization initiator, or an alignment assistant.

In addition, it is preferable that the optically-anisotropic layer 26 has a wide range for the wavelength of incidence light and is formed of a liquid crystal material having a reverse birefringence index dispersion. In addition, it is also preferable that the optically-anisotropic layer can be made to have a substantially wide range for the wavelength of incidence light by imparting a twist component to the liquid crystal composition or by laminating different retardation layers. For example, in the optically-anisotropic layer 26, a method of realizing a λ/2 plate having a wide-range pattern by laminating two liquid crystal layers having different twisted directions is disclosed in, for example, JP2014-089476A and can be preferably used in the present invention.

### —Rod-Like Liquid Crystal Compound—

As the rod-like liquid crystal compound, an azomethine compound, an azoxy compound, a cyanobiphenyl compound, a cyanophenyl ester compound, a benzoate compound, a phenyl cyclohexanecarboxylate compound, a cyanophenylcyclohexane compound, a cyano-substituted phenylpyrimidine compound, an alkoxy-substituted phenylpyrimidine compound, a phenyldioxane compound, a tolan compound, or an alkenylcyclohexylbenzonitrile compound is preferably used. As the rod-like liquid crystal compound, not only the above-described low molecular weight liquid crystal molecules but also polymer liquid crystal molecules can be used.

In the optically-anisotropic layer 26, it is more preferable that the alignment of the rod-like liquid crystal compound is immobilized by polymerization. As the polymerizable rod-like liquid crystal compound, compounds described in Makromol. Chem., (1989), Vol. 190, p. 2255, Advanced Materials (1993), Vol. 5, p. 107, U.S. Pat. Nos. 4,683,327A, 5,622,648A, 5,770,107A, WO95/22586A, WO95/24455A, WO97/00600A, WO98/23580A, WO98/52905A, JP1989-272551A (JP-H1-272551A), JP1994-16616A (JP-H6-16616A), JP1995-110469A (JP-H7-110469A), JP1999-80081A (JP-H11-80081A), and JP2001-64627 can be used. Furthermore, as the rod-like liquid crystal compound, for example, compounds described in JP1999-513019A (JP-H11-513019A) and JP2007-279688A can also be preferably used.

### —Disk-Like Liquid Crystal Compound—

As the disk-like liquid crystal compound, for example, compounds described in JP2007-108732A and JP2010-244038A can be preferably used.

In a case where the disk-like liquid crystal compound is used in the optically-anisotropic layer, the liquid crystal compound 30 rises in the thickness direction in the optically-anisotropic layer, and the optical axis 30A derived from the liquid crystal compound is defined as an axis perpendicular to a disk plane, that is so-called, a fast axis.

The above-described optical element 10 is a transmissive-type optical element 10 through which circularly polarized light transmits and is diffracted. However, the diffractive optical element manufactured using the manufacturing method according to the embodiment of the present invention is not limited thereto.

That is, the diffractive optical element manufactured using the manufacturing method according to the embodiment of the present invention may be a reflective-type diffractive optical element, that is, a reflective-type liquid crystal diffraction element, which includes a cholesteric liquid crystal layer.

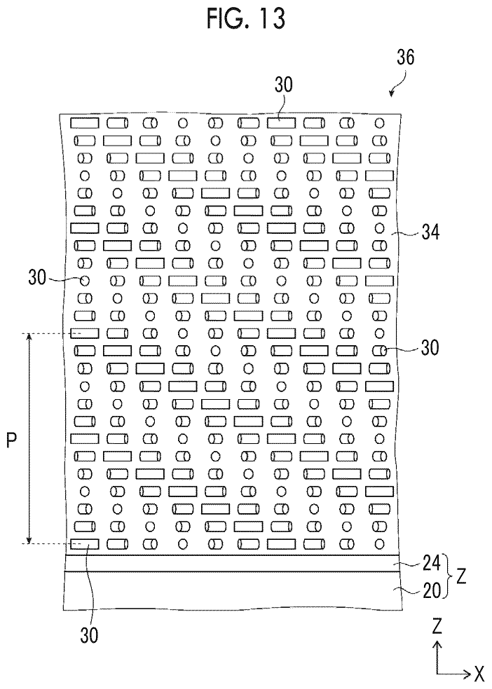

FIG. 13 conceptually shows an example of the reflective-type diffractive optical element manufactured using the manufacturing method according to the embodiment of the present invention. A diffractive optical element 36 shown in FIG. 13 includes a plurality of members that are the same as those in the above-described transmissive-type (diffractive) optical element 10 are used. Therefore, the same members are represented by the same reference numerals, and different portions will be mainly described below. In addition, in the following description, the diffractive optical element 36 will also be referred to as the optical element 36.

FIG. 13 is a diagram conceptually showing a layer configuration of the reflective-type optical element 36. The optical element 36 includes the support 20 and the alignment film 24 described above, and a cholesteric liquid crystal layer 34 that exhibits the action as the reflective-type optical element 36.

Regarding the liquid crystal alignment pattern of the liquid crystal compound 30 in the cholesteric liquid crystal layer 34, as in the optical element 10, as shown in FIG. 8, the liquid crystal alignment pattern in which the optical axis 30A changes while continuously rotating in the one direction indicated by the arrow A is provided in a radial shape.

FIG. 14 is a schematic diagram for describing an alignment state of the liquid crystal compound 30 in a plane of a main surface of the cholesteric liquid crystal layer 34. FIG. 14 shows an alignment state of a facing surface of the cholesteric liquid crystal layer 34A with the alignment film 24.

As in FIG. 10 described above, in the cholesteric liquid crystal layer 34A shown in FIG. 14, in order to describe the cholesteric liquid crystal layer 34, the liquid crystal alignment pattern in which the optical axis 30A changes while continuously rotating in the one direction indicated by the arrow A is shown. However, even in the liquid crystal alignment pattern that includes one direction in which the optical axis changes while continuously rotating in a concentric circular shape (radial shape) from an inner side toward an outer side, the same optical effects as those of the liquid crystal alignment pattern shown in FIG. 14 can be exhibited for the one direction in which the optical axis changes while continuously rotating.

In addition, as in FIG. 10 described above, even in FIG. 14, a circumferential direction of a concentric circle in the concentric circular liquid crystal alignment pattern shown in FIG. 8 corresponds to the Y direction in FIG. 14.

As shown in FIG. 13, the cholesteric liquid crystal layer 34 is a layer obtained by cholesteric alignment of the liquid crystal compound 30. In addition, FIGS. 13 and 14 show an example in which the liquid crystal compound forming the cholesteric liquid crystal layer is a rod-like liquid crystal compound.

In the following description, the cholesteric liquid crystal layer will also be simply referred to as the liquid crystal layer.

In the optical element 36, the support 20 and the alignment film 24 are as described above.

In the optical element 36, the liquid crystal layer 34 (cholesteric liquid crystal layer) having the liquid crystal alignment pattern shown in FIG. 8 is provided on the alignment film 24 having the alignment pattern shown in FIG. 2.

The liquid crystal layer 34 is a cholesteric liquid crystal layer obtained by cholesterically aligning the liquid crystal compound to immobilize a cholesteric liquid crystal phase. In the present example, the cholesteric liquid crystal layer has a liquid crystal alignment pattern in which an orientation of an optical axis derived from a liquid crystal compound changes while continuously rotating in at least one in-plane direction.

As conceptually shown in FIG. 13, the liquid crystal layer 34 has a helical structure in which the liquid crystal compound 30 is helically turned and laminated as in a cholesteric liquid crystal layer obtained by immobilizing a typical cholesteric liquid crystal phase. In the helical structure, a configuration in which the liquid crystal compound 30 is helically rotated once (rotated by) 360° and laminated is set as one helical pitch (helical pitch P), and a plurality of pitches of the helically turned liquid crystal compound 30 are laminated.

As is well known, the cholesteric liquid crystal phase exhibits selective reflectivity with respect to left or right circularly polarized light at a specific wavelength. Whether or not the reflected light is right circularly polarized light or left circularly polarized light is determined depending on a helical twisted direction (sense) of the cholesteric liquid crystal phase. Regarding the selective reflection of the circularly polarized light by the cholesteric liquid crystal phase, in a case where the helical twisted direction of the cholesteric liquid crystal phase is right, right circularly polarized light is reflected, and in a case where the helical twisted direction of the cholesteric liquid crystal phase is left, left circularly polarized light is reflected.

A turning direction of the cholesteric liquid crystal phase can be adjusted by the kind of the liquid crystal compound that forms the cholesteric liquid crystal layer and/or the kind of the chiral agent to be added.

In addition, a half-width Δλ (nm) of a selective reflection range (circularly polarized light reflection range) where selective reflection is exhibited depends on An of the cholesteric liquid crystal phase and the helical pitch P and satisfies a relationship of “Δλ=Δn×helical pitch”. Therefore, the width of the selective reflection range can be controlled by adjusting An. An can be adjusted by adjusting a kind of a liquid crystal compound for forming the cholesteric liquid crystal layer and a mixing ratio thereof, and a temperature during alignment immobilization.

Accordingly, regarding the wavelength of light that is reflected (diffracted) by the liquid crystal layer 34, the selective reflection wavelength range of the liquid crystal layer 34 may be appropriately set, for example, by adjusting the helical pitch P of the liquid crystal layer according to each of the liquid crystal diffraction elements.

As shown in FIG. 14, in the liquid crystal layer 34A, the liquid crystal compounds 30 are arranged in the arrow A direction and the Y direction orthogonal to the arrow A direction. The orientation of the optical axis 30A of the liquid crystal compound 30 changes while continuously rotating in the one in-plane direction in a plane, that is, in the arrow A direction. In addition, in the Y direction, the liquid crystal compounds 30 in which the orientations of the optical axes 30A are the same are arranged at regular intervals.

“The orientation of the optical axis 30A of the liquid crystal compound 30 changes while continuously rotating in the one in-plane direction” represents that as in the optically-anisotropic layer 26, angles between the optical axes 30A of the liquid crystal compounds 30 and the arrow A direction vary depending on positions in the arrow A direction and the angle between the optical axis 30A and the arrow A direction gradually changes from θ to θ+180° or θ−180° in the arrow A direction. That is, in each of the plurality of liquid crystal compounds 30 arranged in the arrow A direction, as shown in FIG. 14, the optical axis 30A changes in the arrow A direction while rotating on a predetermined angle basis.

A difference between the angles of the optical axes 30A of the liquid crystal compound 30 adjacent to each other in the arrow A direction is preferably 45° or less, more preferably 15° or less, and still more preferably less than 15°.

As in the above-described optically-anisotropic layer 26, even in the liquid crystal layer 34, in the liquid crystal alignment pattern of the liquid crystal compound 30, a length (distance) over which the optical axis 30A of the liquid crystal compound 30 rotates by 180° in the arrow A direction in which the optical axis 30A changes while continuously rotating in a plane is set as a length A of the single period in the liquid crystal alignment pattern.

In the liquid crystal alignment pattern of the liquid crystal layer 34, the single period A is repeated in the arrow A direction, that is, in the one direction in which the orientation of the optical axis 30A changes while continuously rotating. The optical element 36 is a liquid crystal diffraction element, and the single period A is the period (single period) of the diffraction structure as described above.

On the other hand, in the liquid crystal compound 30 forming the liquid crystal layer 34, the orientations of the optical axes 30A are the same in the direction (in FIG. 14, the Y direction) orthogonal to the arrow A direction, that is, the Y direction orthogonal to the one direction in which the optical axis 30A continuously rotates. In the liquid crystal alignment pattern shown in FIG. 8, as described above, the Y direction is a circumferential direction of a concentric circle.

In other words, in the liquid crystal compound 30 forming the liquid crystal layer 34, angles between the optical axes 30A of the liquid crystal compound 30 and the arrow A direction (X direction) are the same in the Y direction.

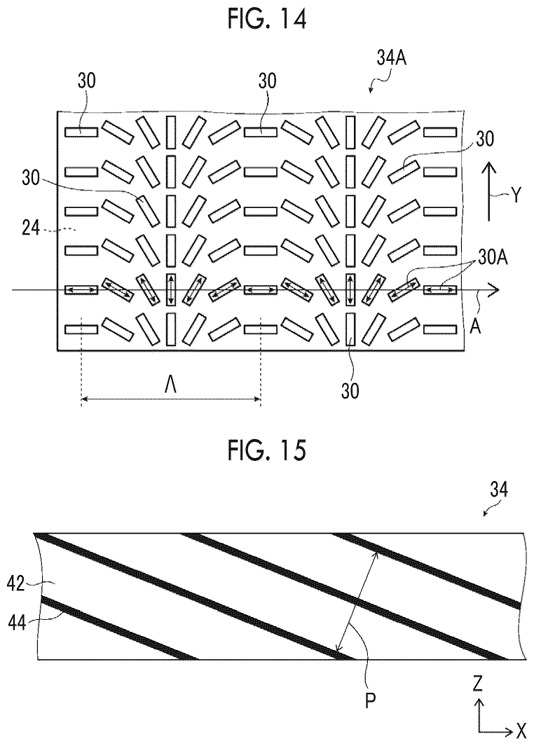

In a case where a cross section of the liquid crystal layer 34 shown in FIG. 13 in the X-Z direction is observed with a scanning electron microscope (SEM), an arrangement direction in which bright portions 42 and dark portions 44 are alternately arranged as shown in FIG. 15, a stripe pattern tilted at a predetermined angle with respect to the main surface (X-Y plane) is observed.

Basically, the interval of the bright portions 42 and the dark portions 44 depends on the helical pitch P of the cholesteric liquid crystal layer.

Accordingly, the wavelength range of light that is selectively reflected from the cholesteric liquid crystal layer correlates to the interval of the bright portions 42 and the dark portions 44. That is, as the interval of the bright portions 42 and the dark portions 44 increases, the helical pitch P increases. Therefore, the wavelength range of light that is selectively reflected from the cholesteric liquid crystal layer increases. Conversely, as the interval of the bright portions 42 and the dark portions 44 decreases, the helical pitch P decreases. Therefore, the wavelength range of light that is selectively reflected from the cholesteric liquid crystal layer decreases.

In the cholesteric liquid crystal layer, basically, a structure in which the bright portion 42 and the dark portion 44 are repeated twice corresponds to the helical pitch P. Accordingly, in the cross section observed with an SEM, an interval between the bright portions 42 adjacent to each other or between the dark portions 44 adjacent to each other in a normal direction (vertical direction) of lines formed by the bright portions 42 or the dark portions 44 corresponds to a ½ pitch of the helical pitch P.

That is, the helical pitch P may be measured by setting the interval between the bright portions 42 or between the dark portions 44 in the normal direction with respect to the lines as a ½ pitch.

Hereinafter, an action of diffraction of the liquid crystal layer 34 will be described.

In a cholesteric liquid crystal layer of the related art, a helical axis derived from a cholesteric liquid crystal phase is perpendicular to the main surface, and a reflecting surface thereof is parallel to the main surface. In addition, the optical axis of the liquid crystal compound is not tilted with respect to the main surface. In other words, the optical axis is parallel to the main surface. Accordingly, in a case where the X-Z plane of the cholesteric liquid crystal layer in the related art is observed with an SEM, an arrangement direction in which bright portions and dark portions are alternately arranged is perpendicular to the main surface.

The cholesteric liquid crystal phase has specular reflectivity. Therefore, for example, in a case where light is incident from the normal direction into the cholesteric liquid crystal layer, the light is reflected in the normal direction.

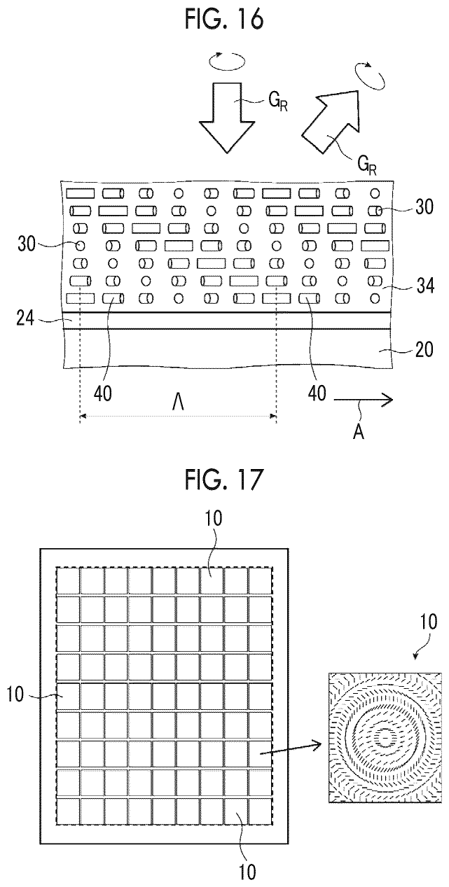

On the other hand, the liquid crystal layer 34 reflects incident light in a state where the light is tilted in the arrow A direction with respect to the specular reflection. The liquid crystal layer 34 has the liquid crystal alignment pattern in which the optical axis 30A changes while continuously rotating in the arrow A direction (the predetermined one direction) in a plane. Hereinafter, the description will be made with reference to FIG. 16.

For example, it is assumed that the liquid crystal layer 34 is a cholesteric liquid crystal layer that selectively reflects right circularly polarized light GR of green light. Accordingly, in a case where light is incident into the liquid crystal layer 34, the liquid crystal layer 34 reflects only right circularly polarized light GR of green light and allows transmission of the other light.

Here, in the liquid crystal layer 34, the optical axis 30A of the liquid crystal compound 30 changes while rotating in the arrow A direction (the one direction).

The liquid crystal alignment pattern formed in the liquid crystal layer 34 is a pattern that is periodic in the arrow A direction. Therefore, as conceptually shown in FIG. 16, the right circularly polarized light GR of green light incident into the liquid crystal layer 34 is reflected (diffracted) in a direction corresponding to the period of the liquid crystal alignment pattern, and the reflected right circularly polarized light GR of green light is reflected (diffracted) in a direction tilted in the arrow A direction with respect to the XY plane. That is, the XY plane is a main surface of the cholesteric liquid crystal layer.

In addition, in a case where circularly polarized lights having the same wavelength and the same turning direction are reflected, by reversing the rotation direction of the optical axis 30A of the liquid crystal compound 30 toward the arrow A direction, a reflection direction of the circularly polarized light can be reversed.

For example, in FIGS. 13 and 14, the rotation direction of the optical axis 30A toward the arrow A direction is clockwise, and one circularly polarized light is reflected in a state where the light is tilted in the arrow A direction. By setting the rotation direction of the optical axis 30A to be counterclockwise, the circularly polarized light is reflected in a state where the light is tilted in a direction opposite to the arrow A direction.

Further, in the liquid crystal layer having the same liquid crystal alignment pattern, the reflection direction is reversed by adjusting the helical turning direction of the liquid crystal compound 30, that is, the turning direction of circularly polarized light to be reflected.

For example, in a case where the helical turning direction of the liquid crystal layer is right-twisted, the liquid crystal layer selectively reflects right circularly polarized light, and has the liquid crystal alignment pattern in which the optical axis 30A rotates clockwise in the arrow A direction. As a result, the right circularly polarized light is reflected in a state where the light is tilted in the arrow A direction.

In addition, for example, in a case where the helical turning direction of the liquid crystal layer is left-twisted, the liquid crystal layer selectively reflects left circularly polarized light, and has the liquid crystal alignment pattern in which the optical axis 30A rotates clockwise in the arrow A direction. As a result, the left circularly polarized light is reflected in a state where the light is tilted in a direction opposite to the arrow A direction.

Accordingly, the optical element 36 can be used as a convex mirror that reflects incidence light to diffuse the light or a concave mirror that reflects incidence light to focus the light depending on the rotation direction of the optical axis 30A from the inner side toward the outer side in the liquid crystal layer 34 and the turning direction of circularly polarized light to be selectively reflected from the liquid crystal layer 34.

As described above, in the liquid crystal layer 34 that acts as the reflective-type optical element 36, in the liquid crystal alignment pattern of the liquid crystal compound 30, the single period Λ as the length over which the optical axis 30A of the liquid crystal compound 30 rotates by 180° is the period (single period) of the diffraction structure. In addition, in the liquid crystal layer 34, the one direction (arrow A direction) in which the optical axis 30A of the liquid crystal compound 30 changes while rotating is the periodic direction of the diffraction structure.

In the liquid crystal layer having the liquid crystal alignment pattern, as the single period Λ decreases, the diffraction angle of reflected light with respect to the incidence light increases. That is, as the single period Λ decreases, incidence light can be largely diffracted to be reflected in a direction that is largely different from specular reflection.

In the present invention, the single period Λ of the liquid crystal layer 34 is not particularly limited, and the single period Λ from which signal light 103 to be assumed can be separated may be appropriately set depending on the wavelength or the like of the signal light 103.

The single period Λ of the liquid crystal layer 34 is preferably 0.1 to 20 μm and more preferably 0.1 to 10 μm.

The liquid crystal layer 34 can be formed by immobilizing a liquid crystal phase in a layer shape, the liquid crystal phase obtained by aligning the liquid crystal compound 30 in a predetermined alignment state. For example, the cholesteric liquid crystal layer can be formed by immobilizing a cholesteric liquid crystal phase in a layer shape.

The structure in which a cholesteric liquid crystal phase is immobilized may be a structure in which the alignment of the liquid crystal compound as a liquid crystal phase is maintained. Typically, it is preferable that the structure in which a cholesteric liquid crystal phase is immobilized is a structure which is obtained by making the polymerizable liquid crystal compound to be in a predetermined alignment state of a liquid crystal phase, polymerizing and curing the polymerizable liquid crystal compound with ultraviolet irradiation, heating, or the like to form a layer having no fluidity, and changing the state of the polymerizable liquid crystal compound into a state where the alignment state is not changed by an external field or an external force at the same time.

The structure in which a liquid crystal phase is immobilized is not particularly limited as long as the optical characteristics of the liquid crystal phase are maintained, and the liquid crystal compound 30 in the liquid crystal layer does not necessarily exhibit liquid crystallinity. For example, the molecular weight of the polymerizable liquid crystal compound may be increased by a curing reaction such that the liquid crystallinity thereof is lost.

Regarding this point, the same can also be applied to the above-described optically-anisotropic layer 26.

Examples of a material used for forming the liquid crystal layer 34 include a liquid crystal composition including a liquid crystal compound. It is preferable that the liquid crystal compound is a polymerizable liquid crystal compound.

Examples of the liquid crystal composition for forming the (cholesteric) liquid crystal layer 34 include a liquid crystal composition obtained by adding a chiral agent for helically aligning the liquid crystal compound 30 to the liquid crystal composition for forming the optically-anisotropic layer 26 of the above-described transmissive-type optical element 36.

### —Chiral Agent (Optically Active Compound)—

The chiral agent has a function of inducing a helical structure of a cholesteric liquid crystal phase. The chiral agent may be selected according to the purpose since the induced helical twisted direction or helical pitch P varies depending on the compound.

The chiral agent is not particularly limited, and a well-known compound (for example, Liquid Crystal Device Handbook (No. 142 Committee of Japan Society for the Promotion of Science, 1989), Chapter 3, Article 4-3, chiral agent for twisted nematic (TN) or super twisted nematic (STN), p. 199), isosorbide, or an isomannide derivative can be used.

In general, the chiral agent includes a chiral carbon atom. However, an axially chiral compound or a planar chiral compound not having a chiral carbon atom can also be used as the chiral agent. Examples of the axially chiral compound or the planar chiral compound include binaphthyl, helicene, paracyclophane, and derivatives thereof. The chiral agent may include a polymerizable group. In a case where both the chiral agent and the liquid crystal compound have a polymerizable group, a polymer having a repeating unit derived from the polymerizable liquid crystal compound and a repeating unit derived from the chiral agent can be formed by a polymerization reaction between the polymerizable chiral agent and the polymerizable liquid crystal compound. In this aspect, it is preferable that the polymerizable group in the polymerizable chiral agent is the same group as the polymerizable group in the polymerizable liquid crystal compound. Accordingly, the polymerizable group of the chiral agent is preferably an unsaturated polymerizable group, an epoxy group, or an aziridinyl group, more preferably an unsaturated polymerizable group, and still more preferably an ethylenically unsaturated polymerizable group.

In addition, the chiral agent may be a liquid crystal compound.

In a case where the chiral agent includes a photoisomerization group, a pattern having a desired reflection wavelength corresponding to a luminescence wavelength can be formed by irradiation of an actinic ray or the like through a photo mask after coating and alignment, which is preferable. As the photoisomerization group, an isomerization portion of a photochromic compound, an azo group, an azoxy group, or a cinnamoyl group is preferable. Specific examples of the compound include compounds described in JP2002-80478A, JP2002-80851A, JP2002-179668A, JP2002-179669A, JP2002-179670A, JP2002-179681A, JP2002-179682A, JP2002-338575A, JP2002-338668A, JP2003-313189A, and JP2003-313292A.

The content of the chiral agent in the liquid crystal composition is preferably 0.01 to 200 mol % and more preferably 1 to 30 mol % with respect to the content molar amount of the liquid crystal compound.

In a case where the liquid crystal layer 34 is formed, it is preferable that the liquid crystal layer 34 is formed by applying the liquid crystal composition to a surface where the liquid crystal layer 34 is to be formed, aligning the liquid crystal compound 30 to a state of a desired liquid crystal phase, and curing the liquid crystal compound 30.

That is, in a case where the cholesteric liquid crystal layer is formed on the alignment film 24, it is preferable that the liquid crystal layer 34 obtained by immobilizing a cholesteric liquid crystal phase is formed by applying the liquid crystal composition to the alignment film 24, aligning the liquid crystal compound 30 to a state of a cholesteric liquid crystal phase, and curing the liquid crystal compound 30.

The applied liquid crystal composition is optionally dried and/or heated and then is cured to form the liquid crystal layer. In the drying and/or heating step, the liquid crystal compound 30 in the liquid crystal composition only has to be aligned to a cholesteric liquid crystal phase. In the case of heating, the heating temperature is preferably 200° C. or lower and more preferably 130° C. or lower.

The aligned liquid crystal compound 30 is optionally further polymerized. Regarding the polymerization, thermal polymerization or photopolymerization using light irradiation may be performed, and photopolymerization is preferable. Regarding this point, the same can also be applied to the above-described optically-anisotropic layer 26.

It is preferable to use ultraviolet rays for the light irradiation. The irradiation energy is preferably 20 mJ/cm² to 50 J/cm² and more preferably 50 to 1500 mJ/cm². In order to promote a photopolymerization reaction, light irradiation may be performed under heating conditions or in a nitrogen atmosphere. The wavelength of the ultraviolet rays to be emitted is preferably 250 to 430 nm.

The thickness of the liquid crystal layer 34 is not particularly limited, and the thickness with which a required light reflectivity can be obtained may be appropriately set depending on the use of the diffraction element, the light reflectivity required for the liquid crystal layer, the material for forming the liquid crystal layer 34, and the like.

As described above, in the manufacturing method according to the embodiment of the present invention, it is preferable that the exposure by the exposure device 50 and the relative movement between the alignment film 24 and the exposure device 50 are repeatedly performed using the alignment film 24 (photosensitive material Z) capable of forming a plurality of diffractive optical elements.

Here, with the exposure device 50 according to the embodiment of the present invention, it is possible to suppress the generation of the non-interference exposure region exposed only to the first light M1 which is a spherical wave having a spread, and preferably, the non-interference exposure region can be almost eliminated by satisfying the above-described expression.

That is, according to the manufacturing method according to the embodiment of the present invention, it is possible to form only a region that acts as a diffractive optical element such as a liquid crystal diffractive lens without having a wasted region that cannot be used.

Therefore, in the optical sheet according to the embodiment of the present invention, which is manufactured using the manufacturing method according to the embodiment of the present invention, the interval between the diffractive optical elements to be manufactured can be made extremely narrow. As a result, in the optical sheet according to the embodiment of the present invention, the number of diffractive optical elements that can be formed on one photosensitive material can be increased as compared with the related art.

Specifically, as shown in FIG. 8, the optical sheet according to the embodiment of the present invention includes a plurality of circular diffractive optical elements each having a concentric circular shape of a liquid crystal alignment pattern in which an orientation of an optical axis of a liquid crystal compound 30 changes while continuously rotating in at least one in-plane direction, and a total area of non-diffractive optical element regions present between the diffractive optical elements is 15% or less of an area of the diffractive optical elements.

That is, as conceptually shown in FIG. 17 as an example, in the optical sheet according to the embodiment of the present invention, in the region where the diffractive optical element 10 is formed, which is indicated by a broken line, the area of the non-diffractive optical element region present between the diffractive optical elements 10 is 15% or less of the area of one diffractive optical element 10.

Accordingly, as described above, in the optical sheet according to the embodiment of the present invention, the number of diffractive optical elements that can be formed on one photosensitive material can be increased as compared with the related art.

In addition, the alignment film according to the embodiment of the present invention includes a plurality of concentric circular alignment patterns (interference patterns) each having a pattern in which an orientation of a line segment changes while continuously rotating in at least one direction, and a total area of non-alignment pattern regions present between the alignment patterns is 15% or less of an area of the alignment patterns.

That is, in a case where the diffractive optical element 10 is regarded as an alignment pattern (interference pattern) in FIG. 17, in the region where the alignment pattern is formed, which is indicated by a broken line, the area of the non-alignment pattern region present between the alignment patterns is 15% or less of the area of one alignment pattern.

Accordingly, as described above, in the alignment film according to the embodiment of the present invention, the number of alignment patterns that can be formed on one photosensitive material can be increased as compared with the related art.

Hereinabove, the exposure device, the method of manufacturing a diffractive optical element, the optical sheet, and the alignment film according to the embodiment of the present invention have been described in detail, but the present invention is not limited to the above-described examples, and various improvements, modifications, and the like can be made within a range not departing from the scope of the present invention.

The present invention can be suitably used for manufacturing various optical elements such as a liquid crystal diffractive lens.

### EXPLANATION OF REFERENCES

10, 36: optical element
20: support
24: alignment film
26, 26A: optically-anisotropic layer
30: liquid crystal compound
30A: optical axis
34, 34A: (cholesteric) liquid crystal layer
50, 100: exposure device
52, 102: light source
54, 104: polarization beam splitter
56A, 56b, 106a, 106b: mirror
58, 108: focusing element
60, 110: beam combiner element
60a: first surface
60b: second surface
62: polarization conversion element
64, 70a: light shielding member
64a, 68a, 70aa, 70ba: opening
68, 70b: polarizer
112: λ/4 plate
M: light having coherence
M1: first light
M2: second light
Z: photosensitive material
Fo: focal point

What is claimed is:

1. An exposure device comprising:
a light source;
a beam splitter element that splits light emitted from the light source;
a beam combiner element that has a first surface on which the light split by the beam splitter element is incident and through which at least a part of incidence light is transmitted and a second surface on which the other light split by the beam splitter element is incident and on which at least a part of incidence light is reflected, and emits light obtained by combining the light transmitted through the first surface and the light reflected from the second surface;
a focusing element that is provided on an optical path of first light incident on the first surface of the beam combiner element or on an optical path of second light incident on the second surface of the beam combiner element, and focuses the light;
an optical element that is provided between the light source and the beam combiner element, and converts the first light and the second light into linearly polarized lights orthogonal to each other;
a polarization conversion element that is disposed on an optical path of the light combined by the beam combiner element;
a light shielding member that is disposed on the optical path of the light combined by the beam combiner element, and shields a part of the linearly polarized light that is not focused by the focusing element; and
a polarizer that is disposed between the beam combiner element and the polarization conversion element, and shields a part of the linearly polarized light that is focused by the focusing element.

2. The exposure device according to claim 1,
wherein a transmissive region of the linearly polarized light in the polarizer is narrower than a transmissive region of the light in the light shielding member.

3. The exposure device according to claim 1,
wherein the polarizer and the light shielding member are provided at the same position in a traveling direction of the light combined by the beam combiner element, and
the light shielding member has an opening and the polarizer is provided at the opening of the light shielding member.

4. The exposure device according to claim 1,
wherein the polarizer and the light shielding member are provided at different positions in a traveling direction of the light combined by the beam combiner element.

5. The exposure device according to claim 1, further comprising:
a support member that supports an exposure target; and
a moving unit that relatively moves the exposure device and the support member.

6. A method of manufacturing a diffractive optical element, comprising:
an exposure step of exposing an alignment film including a compound having a photo-aligned group using the exposure device according to claim 1; and
a film forming step of applying a composition including a liquid crystal compound to the exposed alignment film and drying the composition.

7. The method of manufacturing a diffractive optical element according to claim 6,
wherein in the exposure step, after the alignment film is exposed, the exposure of the alignment film is repeatedly performed again a plurality of times by relatively moving the alignment film and the exposure device in a plane direction of the alignment film.

8. An optical sheet, comprising:
a plurality of diffractive optical elements each having a concentric circular shape of a liquid crystal alignment pattern in which an orientation of an optical axis derived from a liquid crystal compound changes while continuously rotating in at least one in-plane direction,
wherein a total area of non-diffractive optical element regions present between the diffractive optical elements is 15% or less of an area of the diffractive optical elements.

9. An alignment film, comprising:
a plurality of concentric circular alignment patterns each having a pattern in which an orientation of a line segment changes while continuously rotating in at least one direction,
wherein a total area of non-alignment pattern regions present between the alignment patterns is 15% or less of an area of the alignment patterns.

10. The exposure device according to claim 2,
wherein the polarizer and the light shielding member are provided at the same position in a traveling direction of the light combined by the beam combiner element, and
the light shielding member has an opening and the polarizer is provided at the opening of the light shielding member.

11. The exposure device according to claim 2,
wherein the polarizer and the light shielding member are provided at different positions in a traveling direction of the light combined by the beam combiner element.

12. The exposure device according to claim 2, further comprising:
a support member that supports an exposure target; and
a moving unit that relatively moves the exposure device and the support member.

13. A method of manufacturing a diffractive optical element, comprising:
an exposure step of exposing an alignment film including a compound having a photo-aligned group using the exposure device according to claim 2; and
a film forming step of applying a composition including a liquid crystal compound to the exposed alignment film and drying the composition.

14. The method of manufacturing a diffractive optical element according to claim 13,
wherein in the exposure step, after the alignment film is exposed, the exposure of the alignment film is repeatedly performed again a plurality of times by relatively moving the alignment film and the exposure device in a plane direction of the alignment film.

15. The exposure device according to claim 3,
wherein the polarizer and the light shielding member are provided at different positions in a traveling direction of the light combined by the beam combiner element.

16. The exposure device according to claim 3, further comprising:
a support member that supports an exposure target; and
a moving unit that relatively moves the exposure device and the support member.

17. A method of manufacturing a diffractive optical element, comprising:
an exposure step of exposing an alignment film including a compound having a photo-aligned group using the exposure device according to claim 3; and
a film forming step of applying a composition including a liquid crystal compound to the exposed alignment film and drying the composition.

18. The method of manufacturing a diffractive optical element according to claim 17,
wherein in the exposure step, after the alignment film is exposed, the exposure of the alignment film is repeatedly performed again a plurality of times by relatively moving the alignment film and the exposure device in a plane direction of the alignment film.

19. The exposure device according to claim 4, further comprising:
a support member that supports an exposure target; and
a moving unit that relatively moves the exposure device and the support member.

20. A method of manufacturing a diffractive optical element, comprising:
an exposure step of exposing an alignment film including a compound having a photo-aligned group using the exposure device according to claim 4; and
a film forming step of applying a composition including a liquid crystal compound to the exposed alignment film and drying the composition.
